(19) United States
(12) Patent Application Publication
(10) Pub. No.: US 2026/0324154 A1
(43) Pub. Date: Oct. 15, 2026

(54) DISPLAY DEVICE AND ELECTRONIC DEVICE INCLUDING THE SAME

(71) Applicant: Samsung Display Co., Ltd., Yongin-si (KR)

(72) Inventors: Yu Jin KIM, Yongin-si (KR); In Ho KIM, Yongin-si (KR); So Dam BAN, Yongin-si (KR); Bum Jun SO, Yongin-si (KR)

(21) Appl. No.: 19/380,766

(22) Filed: Nov. 5, 2025

(30) Foreign Application Priority Data
Apr. 11, 2025 (KR) 10-2025-0047221

(51) Int. Cl. H10H 29/32; H10D 86/40; H10D 86/60; H10K 59/121; H10K 59/88

(52) U.S. Cl. CPC H10H 29/32; H10D 86/423; H10D 86/431; H10D 86/60; H10K 59/1213; H10K 59/88

(57) ABSTRACT

Provided are display device and electronic device including the same. According to various embodiments of the present disclosure, a display device includes a display area including subpixels including a driving transistor and a switching transistor, and a non-display area closer to the switching transistor than to the driving transistor, surrounding the display area, defining a dummy contact hole penetrating a first gate-insulating layer covering a first active layer, and including a dummy line overlapping the dummy contact hole.

### CROSS-REFERENCE TO RELATED APPLICATION

The present application claims priority to, and the benefit of, Korean Patent Application No. 10-2025-0047221, filed on Apr. 11, 2025, in the Korean Intellectual Property Office, the entire disclosure of which is incorporated herein by reference.

### BACKGROUND

### 1. Field

The present specification relates to a display device, and an electronic device including the same.

### 2. Description of the Related Art

Electroluminescence displays can be divided into inorganic light-emitting displays and organic light-emitting displays depending on the material of a light-emitting layer. An active matrix type organic light-emitting display includes an organic light-emitting diode (OLED) that emits light by itself, and that has advantages of fast response speed, high luminous efficiency, high luminance and wide viewing angle. In the organic light-emitting display, the OLED is formed in each pixel. The organic light-emitting display not only has fast response speed and excellent luminous efficiency, luminance, and viewing angle, but also has excellent contrast ratio and color gamut because it can express a black gray level as complete black.

### SUMMARY

An aspect of the present specification improves the display quality of a display device.

However, aspects of the present specification are not restricted to the one set forth herein. The above and other aspects of the present specification will become more apparent to one of ordinary skill in the art to which the present specification pertains by referencing the detailed description of the present specification given below.

According to various embodiments of the present disclosure, a display device includes a display area including subpixels including a driving transistor and a switching transistor, and a non-display area closer to the switching transistor than to the driving transistor, surrounding the display area, defining a dummy contact hole penetrating a first gate-insulating layer covering a first active layer, and including a dummy line overlapping the dummy contact hole.

A second active layer above the first gate-insulating layer may include a first electrode of the switching transistor, a second electrode of the switching transistor, and a channel portion of the switching transistor between the first electrode of the switching transistor and the second electrode of the switching transistor.

The first active layer may include a silicon semiconductor, wherein the second active layer includes an oxide semiconductor.

The first active layer may include a dummy active layer overlapping the dummy contact hole.

The dummy contact hole may penetrate a second gate-insulating layer covering a first gate metal layer above the first gate-insulating layer.

The dummy contact hole may penetrate a first interlayer insulating film covering a second gate metal layer above the second gate-insulating layer.

A second active layer above the first interlayer insulating film may include a first electrode of the switching transistor, a second electrode of the switching transistor, and a channel portion of the switching transistor between the first electrode of the switching transistor and the second electrode of the switching transistor.

The dummy contact hole may penetrate a third gate-insulating layer covering the second active layer.

A third gate metal layer above the third gate-insulating layer may include a gate electrode of the switching transistor.

The dummy contact hole may penetrate a second interlayer insulating film covering the third gate metal layer.

A first connection metal layer above the second interlayer insulating film may include the dummy line.

The dummy line may include titanium (Ti).

The first active layer may include a dummy active layer overlapping the dummy contact hole, wherein the dummy line contacts the dummy active layer through the dummy contact hole.

The dummy line may be at a layer above a gate electrode of the switching transistor.

The subpixels may include a light-emitting element including an anode above a first connection metal layer including the dummy line, a cathode, and a light-emitting layer between the anode and the cathode.

According to various embodiments of the present disclosure, an electronic device a processor for providing an image signal, a power module for supplying power, and a display module for receiving the image signal from the processor, for receiving the power from the power module, for displaying an image, and including a display area including subpixels including a driving transistor and a switching transistor, and a non-display area closer to the switching transistor than to the driving transistor, surrounding the display area, defining a dummy contact hole penetrating a first gate-insulating layer covering a first active layer, and including a dummy line overlapping the dummy contact hole.

A second active layer above the first gate-insulating layer may include a first electrode of the switching transistor, a second electrode of the switching transistor, and a channel portion of the switching transistor between the first electrode of the switching transistor and the second electrode of the switching transistor.

The first active layer may include a dummy active layer overlapping the dummy contact hole.

The dummy line may contact the dummy active layer through the dummy contact hole.

The dummy line may be at a layer above a gate electrode of the switching transistor.

According to the present specification, a plurality of dummy contact holes, dummy lines, etc. may be additionally placed so that the element characteristics of a subpixel located relatively close to a non-display area can be made similar to those of an inner subpixel. Accordingly, the element characteristics of all subpixels located in a display area may become substantially uniform, and thus the display quality of a display device can be improved.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to one or more embodiments of the present specification;

FIG. 2 is a plan view of the display device of FIG. 1;

FIG. 3 is a cross-sectional view illustrating one or more embodiments of a cross-section taken along the line A-A′ of FIG. 2;

FIG. 4 is a plan view of a display panel according to one or more embodiments of the present specification;

FIG. 5 is a circuit diagram of a pixel according to one or more embodiments of the present specification;

FIGS. 6 through 8 are plan views illustrating a plurality of pixels located in a display area;

FIG. 9 is a cross-sectional view illustrating a first transistor according to one or more embodiments of the present specification;

FIG. 10 is a cross-sectional view illustrating a first transistor according to one or more embodiments of the present specification;

FIGS. 11 through 15 are cross-sectional views for explaining the movement of hydrogen atoms in an area including an oxide transistor;

FIG. 16 is a cross-sectional view for explaining the movement of hydrogen atoms in a unit area including an inner subpixel;

FIG. 17 is a cross-sectional view for explaining the movement of hydrogen atoms in a unit area including a second outer subpixel;

FIG. 18 is a cross-sectional view for explaining the movement of hydrogen atoms in a unit area including a first outer subpixel;

FIG. 19 is a plan view for explaining the movement of hydrogen atoms in the unit area including the inner subpixel;

FIG. 20 is a plan view for explaining the movement of hydrogen atoms in the unit area including the second outer subpixel;

FIG. 21 is a plan view for explaining the movement of hydrogen atoms in the unit area including the first outer subpixel;

FIGS. 22 and 23 are plan views of display devices according to one or more embodiments of the present specification;

FIG. 24 is a plan view of a display device according to one or more embodiments of the present specification;

FIG. 25 is a partial enlarged view of area J of FIG. 24;

FIGS. 26 through 30 are partial enlarged views of various modifications of FIG. 25;

FIGS. 31 through 38 are cross-sectional views illustrating dummy contact holes according to embodiments of the present specification;

FIG. 39 is a block diagram of an electronic device according to one or more embodiments of the present specification; and

FIG. 40 is a schematic diagram of electronic devices according to various embodiments of the present specification.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

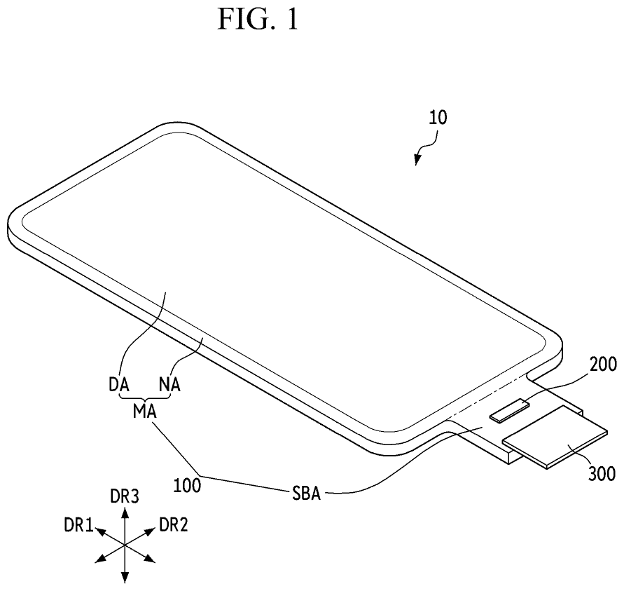

FIG. 1 is a perspective view of a display device 10 according to one or more embodiments of the present specification.

Referring to FIG. 1, the display device 10 is a device for displaying moving images or still images. The display device 10 may be used as a display screen in portable electronic devices, such as mobile phones, smartphones, tablet personal computers (PCs), smart watches, watch phones, mobile communication terminals, electronic notebooks, electronic books, portable multimedia players (PMPs), navigation devices, and ultra-mobile PCs (UMPCs), as well as in various products, such as televisions, notebook computers, monitors, billboards, and Internet of things (IoT) devices.

The display device 10 may be a light-emitting display device, such as an organic light-emitting display device including an organic light-emitting diode, a quantum dot light-emitting display device including a quantum dot light-emitting layer, an inorganic light-emitting display device including an inorganic semiconductor, or a micro-or nano-light-emitting display device using a micro-or nano-light-emitting diode. One or more embodiments in which the display device 10 is an organic light-emitting display device will be described below, but the type of the display device 10 is not limited to an organic light-emitting display device.

In one or more embodiments, the display device 10 may be formed flat. For example, the display device 10 may be formed substantially flat on a plane defined by a first direction DR1 and a second direction DR2, and may have a selected thickness (or height) in a third direction DR3. In one or more embodiments, the display device 10 may include a curved portion in at least one part, such as an edge area. Alternatively, the display device 10 may be flexible so that it can be bent, curved, folded, or rolled.

In one or more embodiments, the first direction DR1 may be a lengthwise direction, a column direction or a vertical direction of an image display surface of the display device 10, and the second direction DR2 may be a direction crossing the first direction DR1, for example, may be a widthwise direction, a row direction or a horizontal direction. The third direction DR3 may be a thickness direction or a height direction of the display device 10.

The display device 10 may include a display panel 100, a driving circuit 200, and a circuit board 300.

The display panel 100 may include a main area MA including a display area DA where an image is displayed, and a sub-area SBA located at a side of the main area MA.

The main area MA may include the display area DA, and a non-display area NA around the display area DA. The display area DA may be located in the center of the main area MA and may occupy most of the main area MA. The non-display area NA may be located at edges of the main area MA and may contact the sub-area SBA.

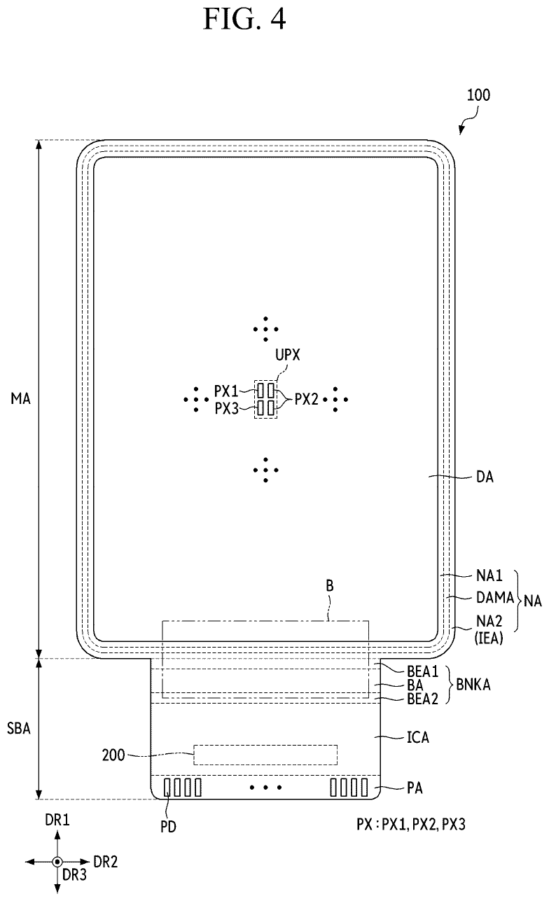

The display area DA may be an area where pixels (e.g., pixels PX of FIG. 4) are arranged, and where an image is displayed by the pixels PX. In one or more embodiments, sensing patterns (e.g., touch electrodes) for detecting a touch input or the like may be further provided in the display area DA, and the display area DA may include a sensing area where a touch input is detected by the sensing patterns.

In one or more embodiments, the display area DA may be shaped like a substantially rectangular plane having long sides in the first direction DR1 and short sides in the second direction DR2. Each corner where a long side and a short side of the display area DA meet may be rounded or right-angled. The shape of the display area DA may vary depending on embodiments. For example, the display area DA may also have a non-quadrangular polygonal shape, a circular shape, or an oval shape.

The non-display area NA may be located immediately around the display area DA. The non-display area NA may surround the display area DA (e.g., in plan view). The non-display area NA may include a dam area and an inorganic encapsulation area. In one or more embodiments, an embedded circuit may be located in the non-display area NA. For example, an embedded circuit, such as a scan-driving circuit, may be located in the non-display area NA on one side (e.g., a left or right side) or on both of opposite sides of the display area DA.

The sub-area SBA may be located on a side of the main area MA. For example, the sub-area SBA may protrude from a side of the main area MA in the first direction DR1. For example, the sub-area SBA may protrude from a lower end of the main area MA in the first direction DR1. In one or more embodiments, the sub-area SBA may be narrower than the main area MA. For example, the sub-area SBA may be narrower than the main area MA in the second direction DR2.

Lines and pads may be provided in the sub-area SBA. For example, lines and pads connected to pixels and/or an embedded circuit located in the main area MA and the driving circuit 200 and/or the circuit board 300 located in the sub-area SBA may be located in the sub-area SBA. In the description of embodiments, the term “connection” may mean electrical connection and/or physical connection.

In one or more embodiments, the driving circuit 200 (e.g., a display-driving circuit) may be mounted on the sub-area SBA. The circuit board 300 may be placed on a portion of the sub-area SBA.

The driving circuit 200 may include a data-driving circuit for driving pixels. In one or more embodiments, the driving circuit 200 may be formed as an integrated circuit and mounted on the sub-area SBA. In one or more embodiments, the driving circuit 200 may be provided on the circuit board 300 on the sub-area SBA or may be provided on another circuit board, which is connected to the display panel 100 through the circuit board 300.

The circuit board 300 may be placed on a portion of the sub-area SBA. For example, the circuit board 300 may be bonded onto pads located in a portion (e.g., a lower edge) of the sub-area SBA, and may supply or transmit power voltages and driving signals for driving the display panel 100 to the display panel 100. For example, the circuit board 300 may supply input image data (e.g., digital image data), driving signals including timing signals, and driving voltages to the display panel 100. The circuit board 300 may be, but is not limited to, a flexible printed circuit board (FPCB), a printed circuit board (PCB), or a flexible film, such as a chip-on-film (COF).

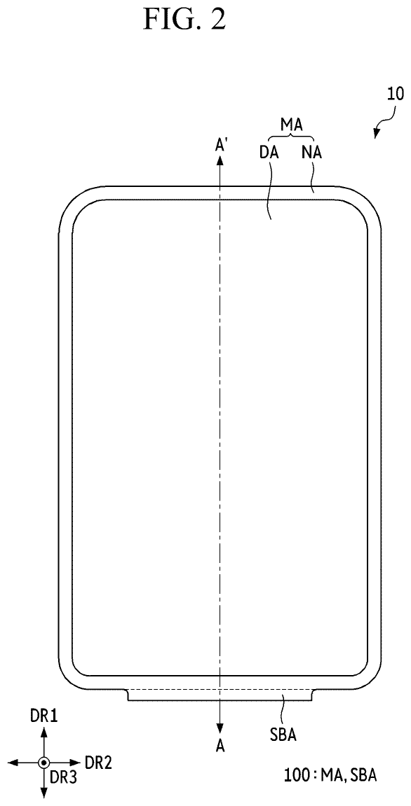

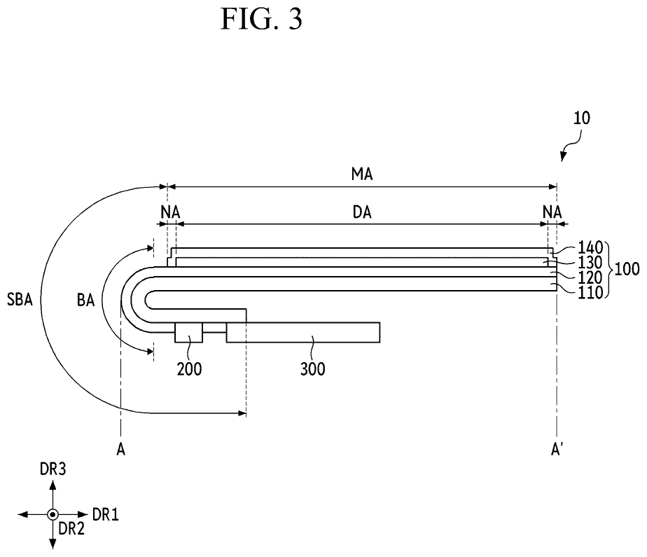

FIG. 2 is a plan view of the display device 10 of FIG. 1. FIG. 3 is a cross-sectional view illustrating one or more embodiments of a cross-section taken along the line A-A′ of FIG. 2.

FIG. 1 illustrates the display device 10 in a state in which the display device 10 is unfolded without being bent, and FIGS. 2 and 3 illustrate the display device 10 in a state in which the display device 10 is bent in the sub-area SBA. For example, FIG. 1 illustrates the display device 10 in a state in which the sub-area SBA is unfolded to lie side by side with the main area MA, and FIGS. 2 and 3 illustrate the display device 10 in a state in which a portion of the sub-area SBA is bent.

Referring to FIGS. 2 and 3, the display panel 100 may include a substrate 110 including the main area MA and the sub-area SBA and a circuit layer 120, a light-emitting element layer 130, and an encapsulation layer 140 sequentially stacked on the substrate 110. The circuit layer 120 may be located on the substrate 110 in the main area MA and the sub-area SBA. The light-emitting element layer 130 and the encapsulation layer 140 may be located on a portion of the substrate 110 and the circuit layer 120 (as used herein, “located on” may mean “above”). For example, the light-emitting element layer 130 and the encapsulation layer 140 may be located in the main area MA.

In one or more embodiments, the display device 10 may further include additional elements located on the display panel 100. For example, the display device 10 may further include at least one of a sensor layer (e.g., a touch sensor layer), a polarizing layer, a color filter layer, or a protective layer (e.g., a window) located on the encapsulation layer 140. The sensor layer, the polarizing layer, the color filter layer and/or the protective layer may be manufactured integrally with the display panel 100 or may be manufactured separately from the display panel 100 and then attached to the display panel 100 by an adhesive layer or the like.

The substrate 110 may include an insulating material, such as polymer resin. For example, the substrate 110 may include polyimide or another insulating material. The substrate 110 may be a flexible substrate that can be bent, folded, or rolled. Alternatively, the substrate 110 may include an insulating material, such as glass.

The circuit layer 120 may include pixel circuits and lines. For example, the circuit layer 120 may include circuit elements (e.g., pixel transistors and a capacitor) constituting a pixel circuit of each pixel and lines connected to the pixels. In one or more embodiments, the circuit layer 120 may further include circuit elements constituting an embedded circuit, such as a scan-driving circuit, and lines connected to the embedded circuit.

The light-emitting element layer 130 may include light-emitting elements provided in emission areas of pixels. For example, each of the pixels may include at least one light-emitting element and a pixel circuit connected to the light-emitting element. Each of the pixels may be located in a pixel area including an emission area where a light-emitting element is placed and a pixel circuit area where a pixel circuit is placed. The emission area and pixel circuit area of each pixel may overlap each other, but embodiments are not limited to this case.

In the description of embodiments, the circuit layer 120 and the light-emitting element layer 130 are described as being separate from each other. However, the embodiments are not limited to this case. For example, the circuit layer 120 and the light-emitting element layer 130 may also be integrated with each other.

The encapsulation layer 140 may cover the light-emitting element layer 130 and may extend to the non-display area NA to contact the circuit layer 120. In one or more embodiments, the encapsulation layer 140 may have a multilayer structure including at least two inorganic encapsulation layers overlapping each other and at least one organic encapsulation layer located between the inorganic encapsulation layers.

In one or more embodiments, the display panel 100 may be bent in a bending area BA. The bending area BA may be a portion of the sub-area SBA, and may be spaced apart from the main area MA.

The substrate 110 and the circuit layer 120 may be bent in the bending area BA corresponding to a portion of the sub-area SBA. Accordingly, a bezel area perceived by a user as the non-display area NA can be reduced or minimized.

FIG. 4 is a plan view of a display panel 100 according to one or more embodiments of the present specification. FIG. 4 illustrates the display panel 100 in an unfolded state without being bent.

Referring to FIG. 4, the display panel 100 may include the main area MA and the sub-area SBA. The main area MA may include the display area DA and the non-display area NA, and the sub-area SBA may include a bank area BNKA, a driving-circuit-mounting area ICA and a pad area PA.

The display area DA may be an area where pixels PX are arranged. The pixels PX and lines (or portions of the lines) connected to the pixels PX may be located in the display area DA.

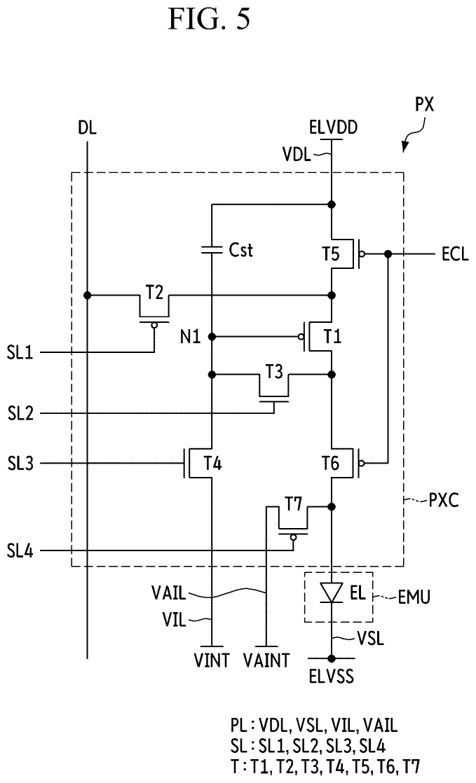

The pixels PX may be provided in the circuit layer 120 and the light-emitting element layer 130 of the display panel 100. For example, each of the pixels PX may include a pixel circuit (e.g., a pixel circuit PXC of FIG. 5) including circuit elements provided in the circuit layer 120 and a light-emitting element (e.g., a light-emitting element EL of FIG. 5) provided in the light-emitting element layer 130.

The pixels PX may include at least two-color pixels PX that emit light of different colors. For example, the pixels PX may include first-color pixels PX1 that emit light of a first color (e.g., red light), second-color pixels PX2 that emit light of a second color (e.g., green light), and third-color pixels PX3 that emit light of a third color (e.g., blue light).

At least one first-color pixel PX1, at least one second-color pixel PX2, and at least one third-color pixel PX3 adjacent to each other may form one unit pixel UPX. For example, one first-color pixel PX1, two second-color pixels PX2, and one third-color pixel PX3 adjacent to each other may form one unit pixel UPX. Each unit pixel UPX may emit light of various colors including white light by mixing the colors of light emitted from the pixels PX that form the unit pixel UPX. In one or more embodiments, the first-color pixels PX1 and the third-color pixels PX3 may be arranged alternately in the first direction DR1 and/or the second direction DR2, and the second-color pixels PX2 may be arranged continuously and/or sequentially in the first direction DR1. The type, shape, and/or arrangement structure of the pixels PX may vary depending on embodiments. In addition, the type, number, ratio, and/or arrangement structure of the pixels PX that form each unit pixel UPX may vary depending on embodiments.

The encapsulation layer 140 may be located on the pixels PX. For example, the encapsulation layer 140 may be provided in at least the display area DA to cover the pixels PX, and a portion of the encapsulation layer 140 may extend to the non-display area NA.

Lines may be provided in the circuit layer 120 and located in the display area DA and the non-display area NA. In addition, the lines may be located in the sub-area SBA. For example, the lines may extend from the sub-area SBA to the display area DA via the non-display area NA.

The non-display area NA may be located around the display area DA. For example, the non-display area NA may be an edge area of the main area MA, which is located outside the display area DA.

The non-display area NA may include a dam area DAMA spaced apart from the display area DA, a first non-display area NA1 between the display area DA and the dam area DAMA, and a second non-display area NA2 outside the dam area DAMA. The dam area DAMA may be an area where a dam surrounding the display area DA is located. The second non-display area NA2 may include an inorganic encapsulation area IEA (also referred to as a “bonding area”) where inorganic encapsulation layers of the encapsulation layer 140 are bonded to each other.

The sub-area SBA may include the bank area BNKA, the driving-circuit-mounting area ICA, and the pad area PA sequentially located on one side of the main area MA. Lines (or portions of the lines), a bank, and pads PD may be located in the sub-area SBA. At least some of the lines may extend to the main area MA and may be connected to the pixels PX.

The bank area BNKA may be an area where a bank including at least one organic layer is located. In one or more embodiments, the bank area BNKA may include the bending area BA. For example, the bank area BNKA may include the bending area BA spaced apart from the main area MA and a first edge area BEA1 and a second edge area BEA2 located on respective sides of the bending area BA in the first direction DR1. The bank may be provided in the bending area BA and in areas around the bending area BA (e.g., the first edge area BEA1 and the second edge area BEA2 of the bank area BNKA) to cover lines passing through the bending area BA. The display panel 100 may be bent in the bending area BA so that a portion of the sub-area SBA is located on a rear surface of the main area MA.

The driving-circuit-mounting area ICA may be an area where the driving circuit 200 is mounted. Pads for connecting at least some lines to the driving circuit 200 may be located in the driving-circuit-mounting area ICA. For example, input pads for connecting the driving circuit 200 to certain pads (e.g., data input pads) of the pad area PA, and output pads for connecting the driving circuit 200 to the pixels PX, may be located in the driving-circuit-mounting area ICA.

In some embodiments, the driving circuit 200 may not be mounted on, or may be omitted from, the display panel 100. In this case, the display panel 100 may not include, or may omit, the driving-circuit-mounting area ICA, and instead only lines may be placed in an area between the bank area BNKA and the pad area PA.

The pad area PA may be an area where the pads PD for connecting the display panel 100 and/or the driving circuit 200 to the circuit board 300 or the like are located. The circuit board 300 may be located or bonded on the pad area PA.

A plurality of pads PD including power pads and signal pads connected to the pixels PX, the driving circuit 200, and/or an embedded circuit may be located in the pad area PA. Power voltages for driving the pixels PX, the driving circuit 200, and/or the embedded circuit may be supplied to the power pads. Driving signals and/or image data for driving the pixels PX, the driving circuit 200, and/or the embedded circuit may be supplied to the signal pads. The type, location, arrangement order, and/or number of pads PD may vary depending on embodiments.

FIG. 5 is a circuit diagram of a pixel PX according to one or more embodiments of the present specification.

In the display device according to the present specification, a pixel circuit may include a plurality of transistors. Each of the transistors may be an oxide thin-film transistor (TFT) including an oxide semiconductor or a low-temperature polysilicon (LTPS) TFT including LTPS.

A transistor is a three-electrode element including a gate, a source, and a drain. The source is an electrode that supplies carriers to the transistor. In the transistor, the carriers start to flow from the source. The drain is an electrode through which the carriers exit the transistor. In the transistor, the carriers flow from the source to the drain.

In the case of an n-channel transistor, the carriers are electrons. Therefore, a source voltage is lower than a drain voltage so that the electrons can flow from the source to the drain. In the n-channel transistor, a current flows from the drain to the source. In the case of a p-channel transistor, the carriers are holes. Therefore, the source voltage is higher than the drain voltage so that the holes can flow from the source to the drain. In the p-channel transistor, because the holes flow from the source to the drain, a current flows from the source to the drain. It should be noted that the source and drain of the transistor are not fixed. For example, the source and the drain can be changed depending on an applied voltage. Therefore, the disclosure is not limited by the source and drain of the transistor.

In the following description, a source electrode and a drain electrode of a transistor may be referred to as a first electrode and a second electrode, respectively. For example, a transistor may include the first electrode and the second electrode. If the first electrode of the transistor is a source electrode, the second electrode of the transistor may be a drain electrode. If the second electrode of the transistor is a source electrode, the first electrode of the transistor may be a drain electrode. The distinction between the source and the drain varies depending on whether the transistor is implemented as an n-channel transistor or a p-channel transistor. In the present specification, the terms “first electrode” and “second electrode” are used regardless of whether a transistor is an n-channel transistor or a p-channel transistor.

Referring to FIG. 5, scan lines SL connected to the pixel PX may include a first scan line SL1, a second scan line SL2, a third scan line SL3, and a fourth scan line SL4, and power lines PL may include a first pixel power line VDL, a second pixel power line VSL, a first initialization power line VIL, and a second initialization power line VAIL. The pixel PX may be further connected to an emission control line ECL.

The pixel PX may include a light-emitting unit EMU including at least one light-emitting element EL and a pixel circuit PXC (also referred to as a “pixel driver”) connected to the light-emitting unit EMU.

The light-emitting element EL may be connected between the second pixel power line VSL to which a second pixel power voltage ELVSS is applied and the pixel circuit PXC. In one or more embodiments, the second pixel power voltage ELVSS may be a low-potential pixel driving voltage. The light-emitting element EL may be a light source of the pixel PX, and may emit light in response to a driving current supplied from the pixel circuit PXC.

The light-emitting element EL may be an organic light-emitting diode. However, embodiments are not limited to this case. For example, the light-emitting element EL may also be an inorganic light-emitting element, a quantum dot light-emitting element, or another type of light-emitting elements.

The pixel circuit PXC may control the light emission timing and luminance of the light-emitting element EL by controlling a driving current supplied to the light-emitting element EL. The pixel circuit PXC may include at least one pixel transistor T and a capacitor Cst. In one or more embodiments, the pixel circuit PXC may include pixel transistors T including first through seventh transistors T1 through T7. The first transistor T1 may be a driving transistor of the pixel PX, and the second through seventh transistors T2 through T7 may be switching transistors of the pixel PX.

The first transistor T1 may include a gate electrode connected to a first node N1, a first electrode electrically connected to the first pixel power line VDL through the fifth transistor T5, and a second electrode electrically connected to the light-emitting unit EMU through the sixth transistor T6. One of the first electrode and the second electrode may be a source electrode, and the other of the first electrode and the second electrode may be a drain electrode. The first transistor T1 may control a source-drain current (hereinafter, referred to as a “driving current”) flowing between the first electrode and the second electrode according to a voltage applied to the gate electrode (e.g., a voltage of the first node N1 corresponding to a voltage of a data signal). For example, the first transistor T1 may be referred to as a driving transistor of the pixel PX.

The second transistor T2 may include a gate electrode connected to the first scan line SL1, a first electrode connected to a data line DL, and a second electrode connected to the first electrode of the first transistor T1. The second transistor T2 may be turned on by a first scan signal supplied to the first scan line SL1 to connect the first electrode of the first transistor T1 to the data line DL. When the second transistor T2 is turned on, the voltage of a data signal supplied to the data line DL may be applied to the first electrode of the first transistor T1.

The third transistor T3 may include a gate electrode connected to the second scan line SL2, a first electrode connected to the second electrode of the first transistor T1, and a second electrode connected to the gate electrode of the first transistor T1 (or the first node N1). The third transistor T3 may be turned on by a second scan signal supplied to the second scan line SL2 to connect the gate electrode and the second electrode of the first transistor T1. When the third transistor T3 is turned on, the first transistor T1 may operate as a diode.

The fourth transistor T4 may include a gate electrode connected to the third scan line SL3, a first electrode connected to the gate electrode of the first transistor T1, and a second electrode connected to the first initialization power line VIL. The fourth transistor T4 may be turned on by a third scan signal supplied to the third scan line SL3 to connect the gate electrode of the first transistor T1 to the first initialization power line VIL. When the fourth transistor T4 is turned on, a first initialization voltage VINT (e.g., a gate initialization voltage) of the first initialization power line VIL may be applied to the gate electrode of the first transistor T1.

The fifth transistor T5 may include a gate electrode connected to the emission control line ECL, a first electrode connected to the first pixel power line VDL, and a second electrode connected to the first electrode of the first transistor T1. The fifth transistor T5 may be turned on by an emission control signal supplied to the emission control line ECL to connect the first electrode of the first transistor T1 to the first pixel power line VDL to which a first pixel power voltage ELVDD is applied. When the fifth transistor T5 is turned on, the first pixel power voltage ELVDD may be applied to the first electrode of the first transistor T1. In one or more embodiments, the first pixel power voltage ELVDD may be a high-potential pixel driving voltage.

The sixth transistor T6 may include a gate electrode connected to the emission control line ECL, a first electrode connected to the second electrode of the first transistor T1, and a second electrode connected to the light-emitting element EL. The sixth transistor T6 may be turned on by an emission control signal supplied to the emission control line ECL to connect the first transistor T1 to the light-emitting element EL. When both the fifth transistor T5 and the sixth transistor T6 are turned on, a driving current of a magnitude corresponding to the voltage of the gate electrode of the first transistor T1 may flow to the light-emitting element EL.

The seventh transistor T7 may include a gate electrode connected to the fourth scan line SL4, a first electrode connected to an anode of the light-emitting element EL, and a second electrode connected to the second initialization power line VAIL. The seventh transistor T7 may be turned on by a fourth scan signal supplied to the fourth scan line SL4 to connect the anode of the light-emitting element EL to the second initialization power line VAIL. The fourth scan signal may be the same signal or a different signal from the first scan signal. When the seventh transistor T7 is turned on, a second initialization voltage VAINT (e.g., an anode initialization voltage) of the second initialization power line VAIL may be applied to the anode of the light-emitting element EL.

The capacitor Cst may be connected between the gate electrode of the first transistor T1 and the first pixel power line VDL. The capacitor Cst may be charged with a voltage corresponding to the voltage of a data signal applied to the gate electrode of the first transistor T1.

An active layer (e.g., a semiconductor pattern including a channel region) of each of the pixel transistors T (e.g., the first through seventh transistors T1 through T7) may include one semiconductor material selected from a silicon semiconductor including polysilicon or amorphous silicon and an oxide semiconductor. In one or more embodiments, some of the pixel transistors T and the other pixel transistors T may be formed as transistors of different conductivity types. In addition, some of the pixel transistors T and the other pixel transistors T may include different types of semiconductor materials.

For example, the first, second, fifth, sixth and seventh transistors T1, T2, T5, T6, and T7 may be formed as P-type transistors (or p-channel transistors) (e.g., P-type metal-oxide-semiconductor field-effect transistors (MOSFETs)), each including an active layer including polysilicon, and the third and fourth transistors T3 and T4 may be formed as N-type transistors (or n-channel transistors) (e.g., N-type MOSFETs), each including an active layer including an oxide semiconductor. In one or more embodiments, transistors, each including an active layer including polysilicon, and transistors, each including an active layer including an oxide semiconductor, may be located in different layers within the circuit layer 120.

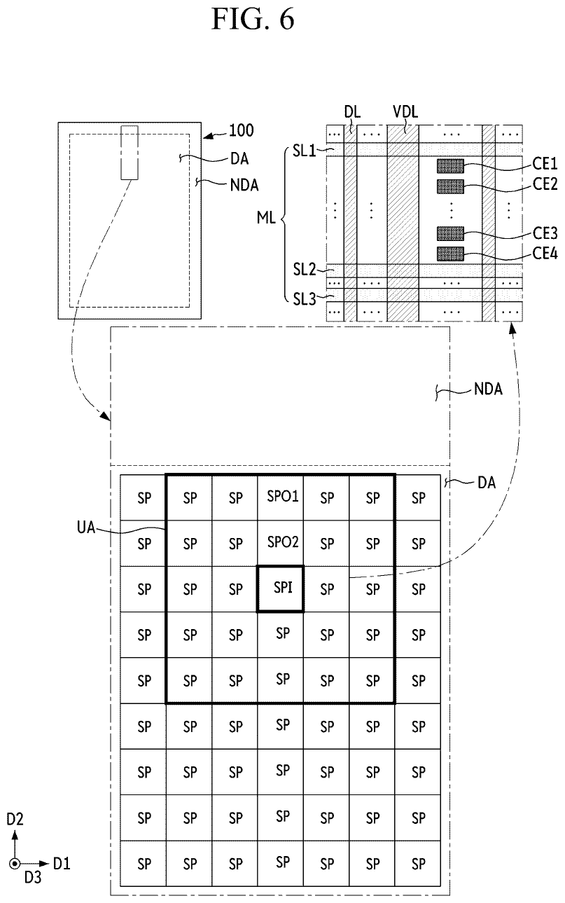

FIGS. 6 through 8 are plan views illustrating a plurality of pixels located in the display area DA.

Referring to FIGS. 6 through 8, the display device may include the display area DA and the non-display area NDA. Referring to an enlarged view, the display area DA may include a plurality of pixels. Each of the pixels may include a plurality of subpixels SP. The subpixels SP may include a first subpixel that realizes a first color, a second subpixel that realizes a second color, and a third subpixel that realizes a third color. The subpixels SP may further include a fourth subpixel that realizes white. The first through third colors may each be selected from red, blue, and green such that they do not overlap each other. For example, the first color may be red, the second color may be green, and the third color may be blue, but embodiments of the present specification are not limited to this example.

The subpixels SP may include an inner subpixel SPI, a first outer subpixel SPO1, and a second outer subpixel SPO2 between the inner subpixel SPI and the first outer subpixel SPO1 in an area adjacent to the non-display area NDA. The first outer subpixel SPO1 may be located closer to the non-display area NDA than the second outer subpixel SPO2 and the inner subpixel SPI. The second outer subpixel SPO2 may be located closer to the non-display area NDA than the inner subpixel SPI. The inner subpixel SPI, the first outer subpixel SPO1, and the second outer subpixel SPO2 may be concepts defined in, for example, a one-dimensional area. For example, the inner subpixel SPI, the second outer subpixel SPO2, and the first outer subpixel SPO1 may be sequentially arranged in a second direction extending from the display area DA toward the non-display area NDA.

Each of the individual subpixels SP may include a plurality of metal lines ML including a data line DL, a first pixel power line VDL, and first through fourth scan lines SL1 through SL4. For example, the first through fourth scan lines SL1 through SL4 may extend in a first direction, and the data line DL and the first pixel power line VDL may extend in the second direction crossing the first direction. In addition, each of the individual subpixels SP may further include a plurality of connection electrodes connecting the metal lines ML. For example, the connection electrodes may include first through fourth connection electrodes CE1 through CE4.

A partial enlarged view of a subpixel SP according to one or more embodiments may show only at least a portion of lines or electrodes located in the subpixel SP. Referring to the description related to the circuit diagram described above, various lines may be placed in addition to the illustrated metal lines ML. For example, a first initialization power line VIL, etc. may be further placed in addition to the illustrated metal lines ML. A partial enlarged view of the illustrated subpixel SP may show only at least a portion of the metal lines ML or connection electrodes located in the subpixel SP.

In an area adjacent to the non-display area NDA, a unit area UA of a certain size may be defined. The unit area UA may be defined based on a subpixel SP serving as its center. The subpixel SP located at the center of the unit area UA may be different in each unit area UA.

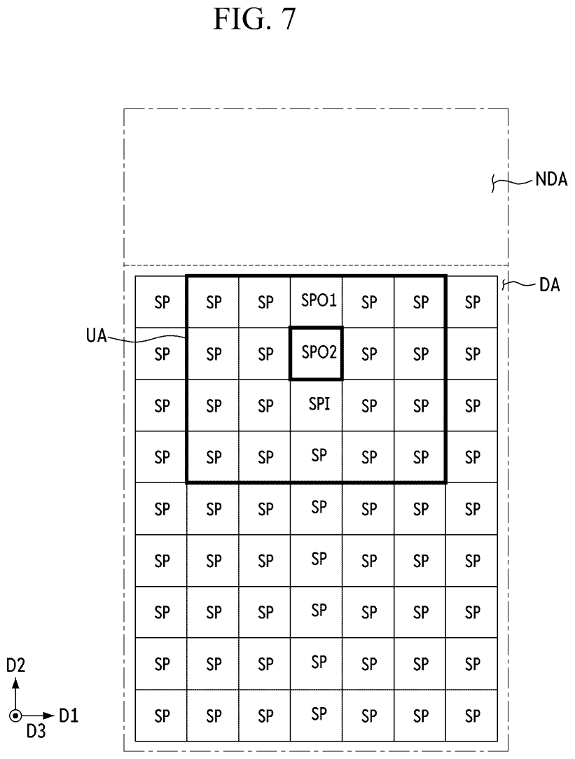

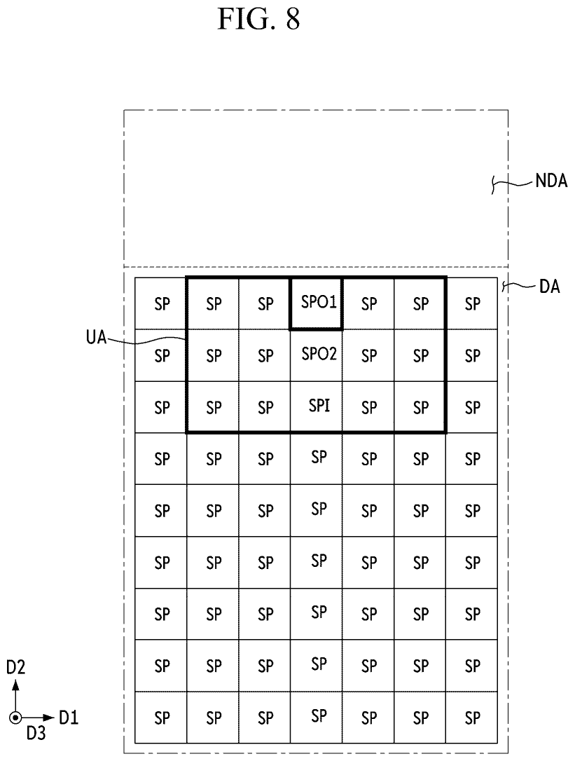

Referring to FIG. 6, when a unit area UA is defined based on the inner subpixel SPI, the inner subpixel SPI may be surrounded by, for example, twenty-four subpixels SP. Referring to FIG. 7, when a unit area UA is defined based on the second outer subpixel SPO2, the second outer subpixel SPO2 may be surrounded by, for example, nineteen subpixels SP. Referring to FIG. 8, when a unit area UA is defined based on the first outer subpixel SPO1, the first outer subpixel SPO1 may be surrounded by, for example, fourteen subpixels SP. The size of the unit area UA may vary, but the number of subpixels SP placed per unit area UA of a certain size may decrease in the order of the inner subpixel SPI, the second outer subpixel SPO2, and the first outer subpixel SPO1.

Each subpixel SP may include a plurality of metal lines ML and connection electrodes as described above. Here, the closer the subpixel SP is to the non-display area NDA, the smaller the total amount (e.g., mass, etc.) of the metal lines ML and connection electrodes surrounding the subpixel SP. As will be described later, when the amount of the metal lines ML or connection electrodes surrounding a subpixel SP serving as a basis decreases, the influence of the metal lines ML and connection electrodes on the subpixel SP serving as a basis may decrease.

The display device according to embodiments of the present specification can solve a problem caused by a reduction in the metal lines ML and connection electrodes that affect the element characteristics of a subpixel SP as the subpixel SP is closer to the non-display area NDA.

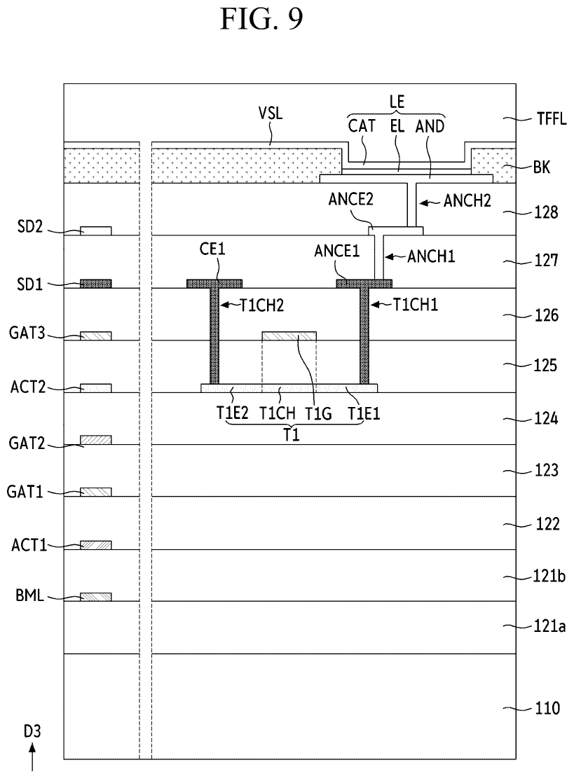

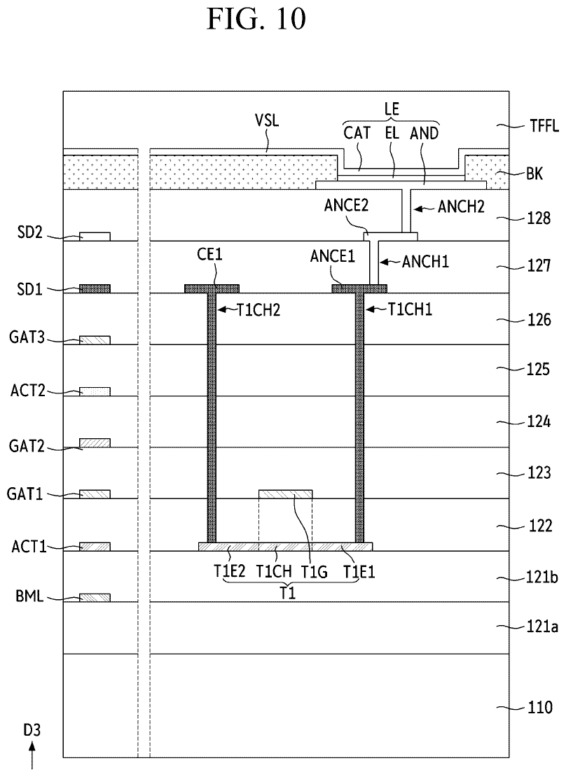

FIG. 9 is a cross-sectional view illustrating a first transistor according to one or more embodiments of the present specification. FIG. 10 is a cross-sectional view illustrating a first transistor according to one or more embodiments of the present specification.

Referring to FIG. 9, the display device according to embodiments of the present specification may include a substrate 110 and a plurality of insulating layers. The insulating layers may include a first buffer layer 121a, a second buffer layer 121b, a first gate-insulating layer 122, a second gate-insulating layer 123, a first interlayer insulating film 124, a third gate-insulating layer 125, and a second interlayer insulating film 126, but embodiments of the present specification are not limited to this case. The display device may further include a planarization layer(s) (127 and/or 128) located on the insulating layers. The planarization layer may be formed as a multilayer including a first planarization layer 127 and a second planarization layer 128, but embodiments of the present specification are not limited to this case.

The first buffer layer 121a may be formed on the substrate 110 of the display device, and a bottom metal layer BML may be formed on the first buffer layer 121a. A first active layer ACT1 may be formed on the second buffer layer 121b. A first gate metal layer GAT1 may be formed on the first gate-insulating layer 122. A second gate metal layer GAT2 may be formed on the second gate-insulating layer 123. A second active layer ACT2 may be formed on the first interlayer insulating film 124. A third gate metal layer GAT3 may be formed on the third gate-insulating layer 125. A first connection metal layer SD1 may be formed on the second interlayer insulating film 126. A second connection metal layer SD2 may be located on the first planarization layer 127.

An element layer may be formed on the second planarization layer 128. The element layer may include a light-emitting element LE and a bank BK. The light-emitting element LE may include an anode AND, a light-emitting layer EL, and a cathode CAT. The bank BK may cover at least a portion of an end portion and/or the other end portion of the anode AND and may define an emission area.

The substrate 110 may include an insulating material, such as polymer resin or glass. The substrate 110 may include a glass material. The substrate 110 may include polyimide. In this case, the substrate 110 may be a flexible substrate that can be bent, folded, or rolled.

The first buffer layer 121a located on the substrate 110 may include a silicon nitride layer, a silicon oxynitride layer, a silicon oxide layer, a titanium oxide layer, or an aluminum oxide layer.

The bottom metal layer BML located on the first buffer layer 121a may be a single layer or a multilayer including any one or more of molybdenum (Mo), aluminum (Al), chromium (Cr), gold (Au), titanium (Ti), nickel (Ni), neodymium (Nd), copper (Cu), and/or alloys thereof.

The second buffer layer 121b covering the bottom metal layer BML may include a silicon nitride layer, a silicon oxynitride layer, a silicon oxide layer, a titanium oxide layer, or an aluminum oxide layer. The second buffer layer 121b may include an inorganic layer that can reduce or prevent penetration of air or moisture. The second buffer layer 121b may include a plurality of inorganic layers stacked alternately.

The first active layer ACT1 located on the second buffer layer 121b may include a silicon semiconductor, such as polycrystalline silicon, monocrystalline silicon, low-temperature polycrystalline silicon, or amorphous silicon. An electrode may be formed when the first active layer ACT1 is doped with ions or impurities. The doped first active layer ACT1 may have conductivity.

The first gate-insulating layer 122 covering the first active layer ACT1 may include an inorganic layer, for example, a silicon nitride layer, a silicon oxynitride layer, a silicon oxide layer, a titanium oxide layer, or an aluminum oxide layer.

The first gate metal layer GAT1 located on the first gate-insulating layer 122 may be a single layer or a multilayer including any one or more of molybdenum (Mo), aluminum (Al), chromium (Cr), gold (Au), titanium (Ti), nickel (Ni), neodymium (Nd), copper (Cu), and/or alloys thereof.

The second gate-insulating layer 123 covering the first gate metal layer GAT1 may include an inorganic layer, for example, a silicon nitride layer, a silicon oxynitride layer, a silicon oxide layer, a titanium oxide layer, or an aluminum oxide layer.

The second gate metal layer GAT2 located on the second gate-insulating layer 123 may be a single layer or a multilayer including any one or more of molybdenum (Mo), aluminum (Al), chromium (Cr), gold (Au), titanium (Ti), nickel (Ni), neodymium (Nd), copper (Cu), and/or alloys thereof.

The first interlayer insulating film 124 covering the second gate metal layer GAT2 may include an inorganic layer, for example, a silicon nitride layer, a silicon oxynitride layer, a silicon oxide layer, a titanium oxide layer, or an aluminum oxide layer.

The second active layer ACT2 located on the first interlayer insulating film 124 may include an oxide semiconductor. An electrode may be formed when the second active layer ACT2 is doped with ions or impurities. The doped second active layer ACT2 may have conductivity.

In one or more embodiments, the first active layer ACT1 may include a polycrystalline silicon semiconductor material, and the second active layer ACT2 may include an oxide semiconductor material. Therefore, at least some of the transistors of a pixel circuit may be implemented as oxide TFTs, and at least some other transistors may be implemented as LTPS TFTs. Because oxide TFTs and LTPS TFTs are used in combination, it is possible to ensure efficiency in terms of manufacturing cost of a display device while securing electron mobility, etc. Accordingly, a display device with improved color gamut, power consumption, etc. can be provided.

The third gate-insulating layer 125 covering the second active layer ACT2 may include an inorganic layer, for example, a silicon nitride layer, a silicon oxynitride layer, a silicon oxide layer, a titanium oxide layer, or an aluminum oxide layer.

The third gate metal layer GAT3 located on the third gate-insulating layer 125 may be a single layer or a multilayer including any one or more of molybdenum (Mo), aluminum (Al), chromium (Cr), gold (Au), titanium (Ti), nickel (Ni), neodymium (Nd), copper (Cu), and/or alloys thereof.

The second interlayer insulating film 126 covering the third gate metal layer GAT3 may include an inorganic layer, for example, a silicon nitride layer, a silicon oxynitride layer, a silicon oxide layer, a titanium oxide layer, or an aluminum oxide layer.

The first connection metal layer SD1 located on the second interlayer insulating film 126 may be a single layer or a multilayer including any one or more of molybdenum (Mo), aluminum (Al), chromium (Cr), gold (Au), titanium (Ti), nickel (Ni), neodymium (Nd), copper (Cu), and/or alloys thereof.

The first planarization layer 127 covering the first connection metal layer SD1 may include an organic layer, such as acryl resin, epoxy resin, phenolic resin, polyamide resin, or polyimide resin.

The second connection metal layer SD2 located on the first planarization layer 127 may be a single layer or a multilayer including any one or more of molybdenum (Mo), aluminum (Al), chromium (Cr), gold (Au), titanium (Ti), nickel (Ni), neodymium (Nd), copper (Cu), and/or alloys thereof.

The second planarization layer 128 covering the second connection metal layer SD2 may include an organic layer, such as acryl resin, epoxy resin, phenolic resin, polyamide resin, or polyimide resin.

The light-emitting element LE including the anode AND, the light-emitting layer EL, and the cathode CAT may be located on the second planarization layer 128. The anode AND may be electrically connected or in contact with an anode connection electrode ANCE1 and/or ANCE2 through an anode contact hole ANCH1 and/or ANCH2 formed in the first planarization layer 127 and/or the second planarization layer 128. In one or more embodiments, a first anode connection electrode ANCE1 and a second anode connection electrode ANCE2 may be configured as one anode connection electrode. In this case, the first planarization layer 127 and the second planarization layer 128 may also be configured as one planarization layer.

In a top emission structure in which light is emitted from the light-emitting layer EL toward the cathode CAT, the anode AND may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank BK may be formed on the second planarization layer 128 to delimit the anode AND to define an emission area EA. The emission area EA is an area in which the anode AND, the light-emitting layer EL, and the cathode CAT are sequentially stacked so that holes from the anode AND and electrons from the cathode CAT are combined with each other in the light-emitting layer EL to emit light. The bank BK may cover edges of the anode AND. The bank BK may include an organic layer, such as acryl resin, epoxy resin, phenolic resin, polyamide resin, or polyimide resin.

The light-emitting layer EL may be formed on the anode AND. The light-emitting layer EL may include an organic material to emit light of a selected color. For example, the light-emitting layer EL may include a hole-transporting layer, an organic material layer, and an electron-transporting layer.

The cathode CAT may be formed on the light-emitting layer EL. The cathode CAT may cover the light-emitting layer EL. The cathode CAT may be a common layer formed in common in all emission areas EA including the illustrated emission area EA. A capping layer may be formed on the cathode CAT.

In the top emission structure, the cathode CAT may include a transparent conductive oxide (TCO) that can transmit light, such as indium tin oxide (ITO) or indium zinc oxide (IZO), or a semi-transmissive conductive material, such as magnesium (Mg), silver (Ag) or an alloy of Mg and Ag. When the cathode CAT includes a semi-transmissive conductive material, light output efficiency may be increased by a microcavity.

An encapsulating layer TFEL may be located on the cathode CAT. The encapsulating layer TFEL may include at least one inorganic layer to reduce or prevent oxygen or moisture from permeating into the light-emitting element LE. In addition, the encapsulation layer TFEL may include at least one organic layer to protect the light-emitting element LE from foreign substances, such as dust. For example, the encapsulation layer TFEL may include a plurality of inorganic layers and a single organic layer, but embodiments of the present specification are not limited to this example. The inorganic layer may be a multilayer in which one or more inorganic layers selected from a silicon nitride layer, a silicon oxynitride layer, a silicon oxide layer, a titanium oxide layer, and an aluminum oxide layer are alternately stacked. The organic layer may include acryl resin, epoxy resin, phenolic resin, polyamide resin, or polyimide resin.

A filling layer, a sealant, and an encapsulation substrate may replace the encapsulation layer TFEL. In this case, the encapsulation substrate may be an insulating substrate including an insulating material, such as glass or plastic. The filling layer may be, but is not limited to, an air layer in a vacuum state. The sealant may be located in a non-display area of a display panel to surround a display area.

In one or more embodiments, a first transistor T1 may include an oxide semiconductor. Therefore, the second active layer ACT2 may include a first electrode T1E1 of the first transistor T1, a second electrode T1E2 of the first transistor T1, and a channel portion T1CH of the first transistor T1 located between the first electrode T1E1 of the first transistor T1 and the second electrode T1E2 of the first transistor T1. The third gate metal layer GAT3 may include a gate electrode T1G of the first transistor T1. The gate electrode T1G of the first transistor T1 and the channel portion T1CH of the first transistor T1 may overlap each other in the thickness direction of the display device.

The first transistor T1 may be implemented as a p-channel transistor as in the circuit diagram described above. In this case, the second electrode T1E2 of the first transistor T1 may be a source electrode, and the first electrode T1E1 of the first transistor T1 may be a drain electrode. However, embodiments of the present specification are not limited to this case.

The first connection metal layer SD1 may include a first connection electrode CE1 and the first anode connection electrode ANCE1. The first connection electrode CE1 may be electrically connected or in contact with the second electrode T1E2 of the first transistor T1 through a second contact hole T1CH2. The first anode connection electrode ANCE1 may be electrically connected or in contact with the first electrode T1E1 of the first transistor T1 through a first contact hole T1CH1.

The second connection metal layer SD2 may include the second anode connection electrode ANCE2, and the second anode connection electrode ANCE2 may be electrically connected or in contact with the first electrode T1E1 of the first transistor T1 through a first anode contact hole ANCH1. The anode AND may be electrically connected or in contact with the second anode connection electrode ANCE2 through a second anode contact hole ANCH2.

In one or more embodiments, the first contact hole T1CH1 and the second contact hole T1CH2 may be formed in the third gate-insulating layer 125 and in the second interlayer insulating film 126. The first anode contact hole ANCH1 may be formed in the first planarization layer 127, and the second anode contact hole ANCH2 may be formed in the second planarization layer 128.

Referring to FIG. 10, in one or more embodiments, a first transistor T1 may include a silicon semiconductor. Therefore, the first active layer ACT1 may include a first electrode T1E1 of the first transistor T1, a second electrode T1E2 of the first transistor T1, and a channel portion T1CH of the first transistor T1 located between the first electrode T1E1 of the first transistor T1 and the second electrode T1E2 of the first transistor T1. The first gate metal layer GAT1 may include a gate electrode T1G of the first transistor T1. The gate electrode T1G of the first transistor T1 and the channel portion T1CH of the first transistor T1 may overlap each other in the thickness direction of the display device.

The first transistor T1 may be implemented as a p-channel transistor as in the circuit diagram described above. In this case, the second electrode T1E2 of the first transistor T1 may be a source electrode, and the first electrode T1E1 of the first transistor T1 may be a drain electrode. However, embodiments of the present specification are not limited to this case.

The first connection metal layer SD1 may include a first connection electrode CE1 and a first anode connection electrode ANCE1. The first connection electrode CE1 may be electrically connected or in contact with the second electrode T1E2 of the first transistor T1 through a second contact hole T1CH2. The first anode connection electrode ANCE1 may be electrically connected or in contact with the first electrode T1E1 of the first transistor T1 through a first contact hole T1CH1.

The second connection metal layer SD2 may include a second anode connection electrode ANCE2. The second anode connection electrode ANCE2 may be electrically connected to, or in contact with, the first electrode T1E1 of the first transistor T1 through a first anode contact hole ANCH1 (e.g., via a first anode connection electrode ANCE1 and a first contact hole T1CH1). An anode AND may be electrically connected or in contact with the second anode connection electrode ANCE2 through a second anode contact hole ANCH2.

In one or more embodiments, the first contact hole T1CH1 and the second contact hole T1CH2 may be formed in the first gate-insulating layer 122, the second gate-insulating layer 123, the first interlayer insulating film 124, the third gate-insulating layer 125, and the second interlayer insulating film 126. The first anode contact hole ANCH1 may be formed in the first planarization layer 127, and the second anode contact hole ANCH2 may be formed in the second planarization layer 128.

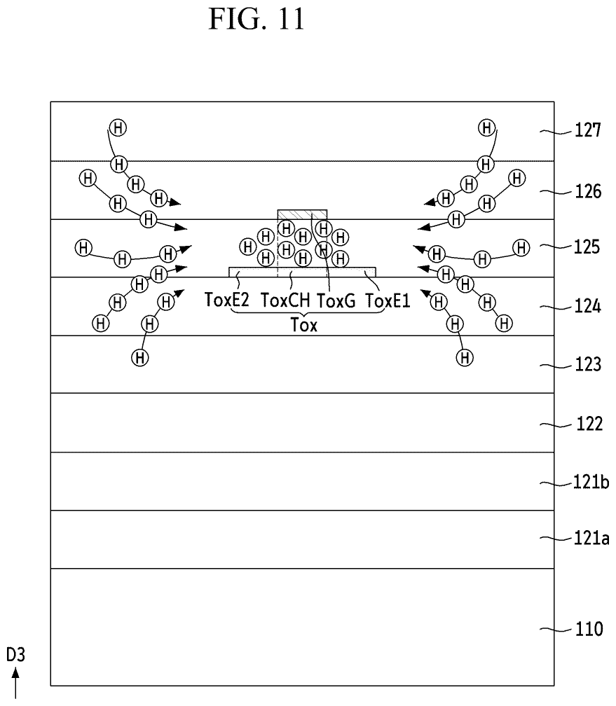

FIGS. 11 through 15 are cross-sectional views for explaining the movement of hydrogen atoms in an area including an oxide transistor.

Referring to FIG. 11, an oxide transistor Tox according to one or more embodiments may include an oxide semiconductor. Therefore, the second active layer may include a first electrode ToxE1 of the oxide transistor Tox, a second electrode ToxE2 of the oxide transistor Tox, and a channel portion ToxCH of the oxide transistor Tox located between the first electrode ToxE1 of the oxide transistor Tox and the second electrode ToxE2 of the oxide transistor Tox. The third gate metal layer GAT3 may include a gate electrode ToxG of the oxide transistor Tox. The gate electrode ToxG of the oxide transistor Tox and the channel portion ToxCH of the oxide transistor Tox may overlap each other in the thickness direction of the display device.

A plurality of insulating layers may supply hydrogen to an oxide semiconductor layer including an oxide semiconductor during a process of manufacturing the display device. For example, the second active layer may be an oxide semiconductor layer. Hydrogen generated in the process of manufacturing the display device may act as a carrier when absorbed by the oxide semiconductor layer, and the characteristics of a transistor including the oxide semiconductor layer may change depending on the degree of inflow of hydrogen.

The amount of hydrogen to be absorbed by the oxide semiconductor layer during the process of manufacturing the display device may be controlled by appropriately selecting the thicknesses, materials, etc. of the insulating layers (121a, 121b, 122, 123, 124, 125, 126).

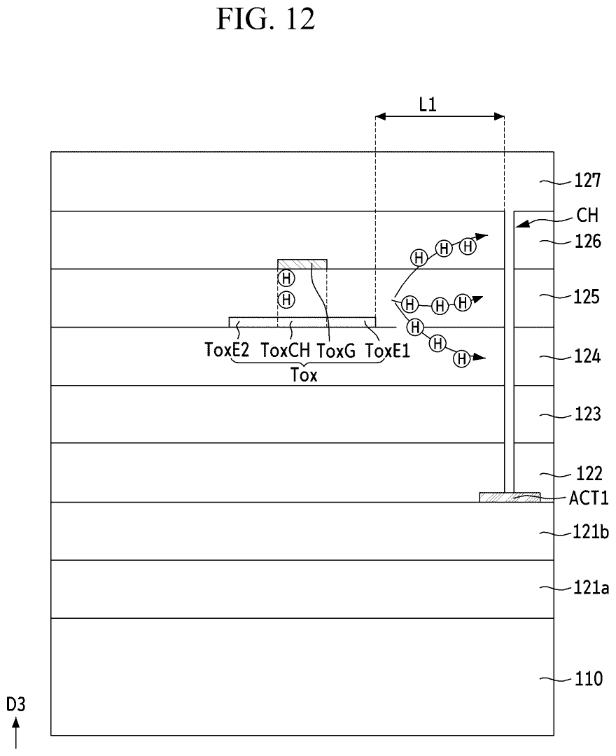

Referring to FIG. 12, a contact hole CH may be provided in an area adjacent to the oxide transistor Tox. The contact hole CH may perform a function of capturing hydrogen (H) that has been absorbed by the oxide semiconductor layer. For example, the contact hole CH may be formed in the first gate-insulating layer 122, the second gate-insulating layer 123, the first interlayer insulating film 124, the third gate-insulating layer 125, and the second interlayer insulating film 126. The amount of hydrogen (H) to be captured by the contact hole CH may be controlled by adjusting a distance L1 between the oxide transistor Tox and the contact hole CH.

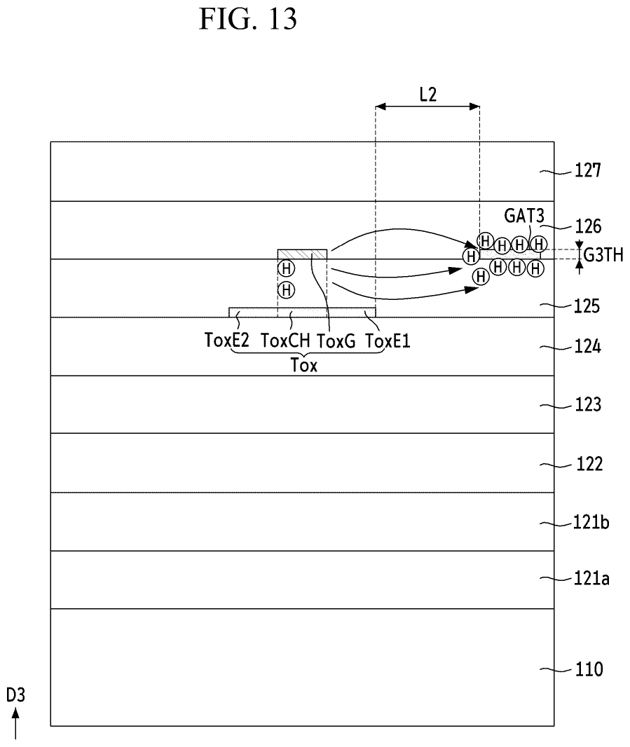

Referring to FIG. 13, the third gate metal layer GAT3 may also be provided in the area adjacent to the oxide transistor Tox. The third gate metal layer GAT3 may also perform the function of capturing hydrogen (H) that has been absorbed by the oxide semiconductor layer. The third gate metal layer GAT3 may include titanium (Ti), and the titanium (Ti) included in the third gate metal layer GAT3 may capture hydrogen (H) that has been absorbed by the oxide semiconductor layer. The amount of hydrogen (H) to be captured may be controlled by adjusting a distance L2 between the oxide transistor Tox and the third gate metal layer GAT3 and a thickness G3TH of the third gate metal layer GAT3.

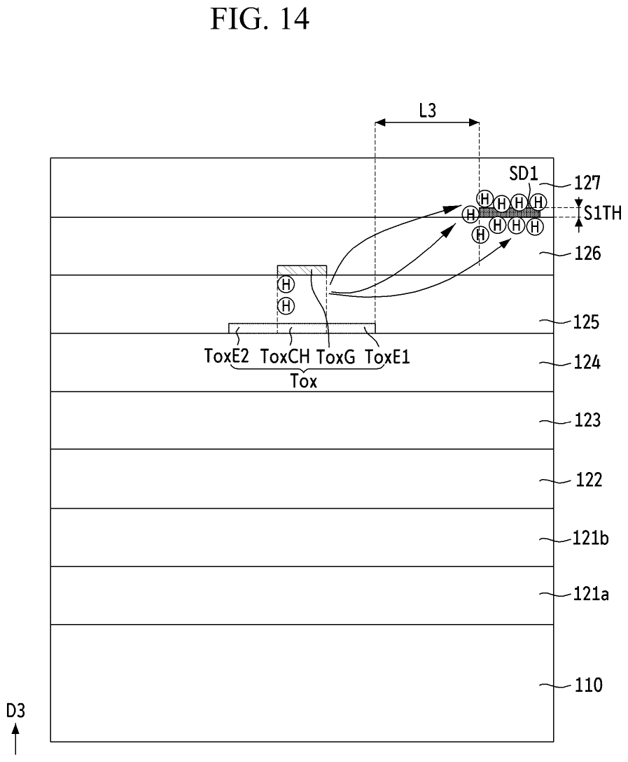

Referring to FIG. 14, the first connection metal layer SD1 may also be provided in the area adjacent to the oxide transistor Tox. The first connection metal layer SD1 may also perform the function of capturing hydrogen (H) that has been absorbed by the oxide semiconductor layer. The first connection metal layer SD1 may include titanium (Ti), and the titanium (Ti) included in the first connection metal layer SD1 may capture hydrogen (H) that has been absorbed by the oxide semiconductor layer. The amount of hydrogen (H) to be captured may be controlled by adjusting a distance L3 between the oxide transistor Tox and the first connection metal layer SD1 and a thickness S1TH of the first connection metal layer SD1.

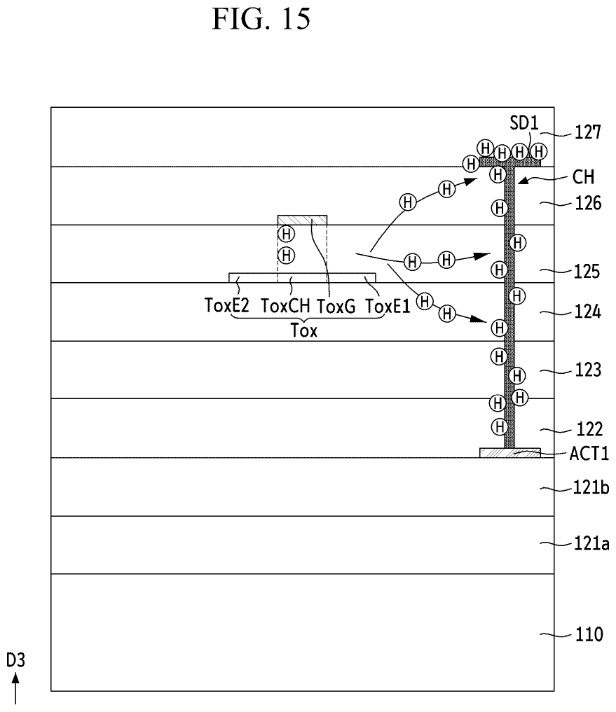

Referring to FIG. 15, a structure including the contact hole CH, the first connection metal layer SD1, and the first active layer ACT1 electrically connected or in contact with the first connection metal layer SD1 may be provided in the area adjacent to the oxide transistor Tox. The contact hole CH and the titanium (Ti) included in the first connecting metal layer SD1 may capture hydrogen (H) from the oxide transistor Tox, and the amount of hydrogen (H) in the oxide semiconductor layer may be controlled by the above structure.

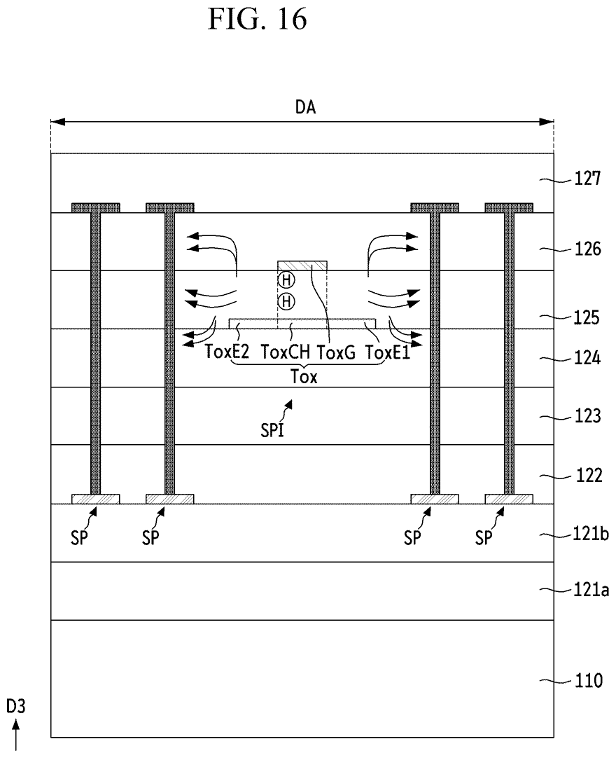

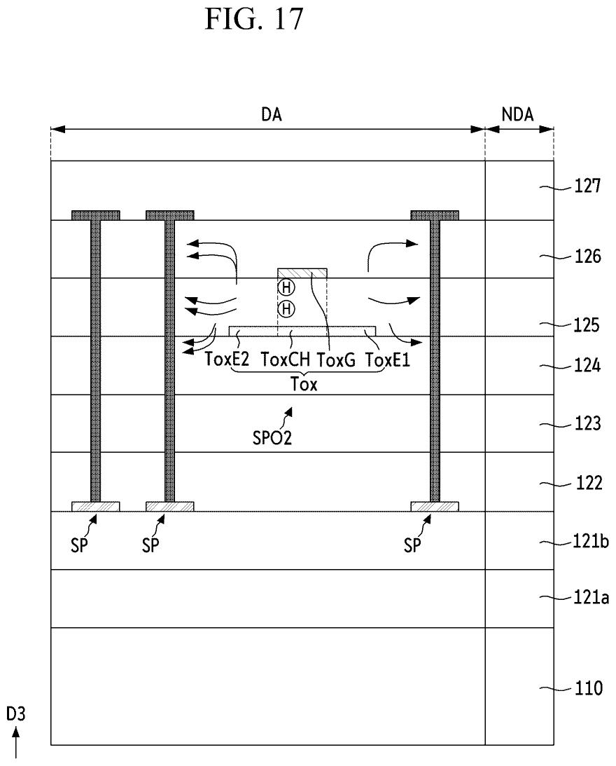

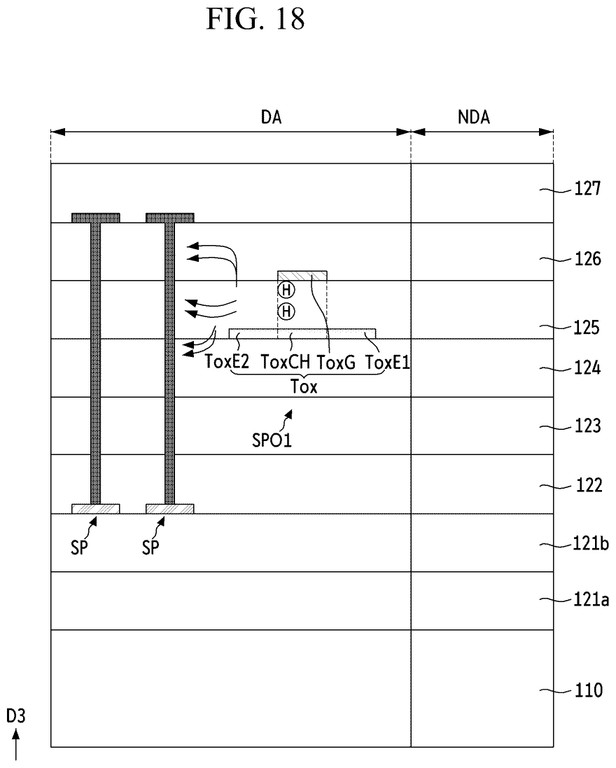

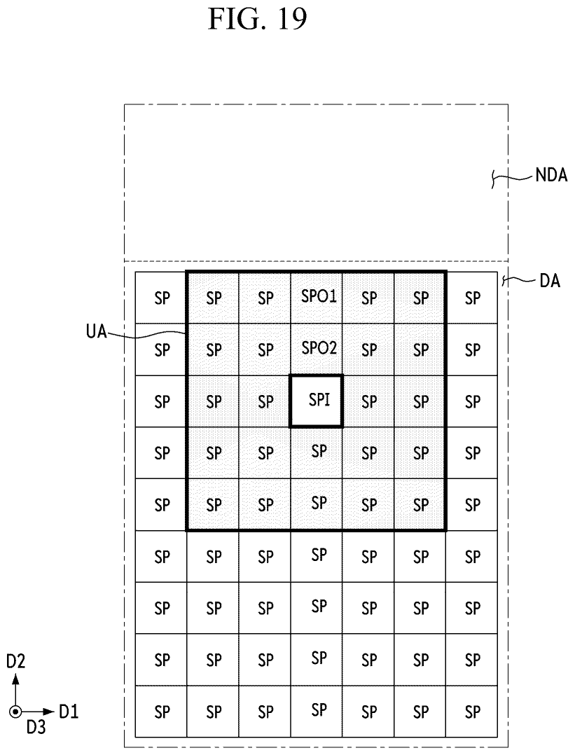

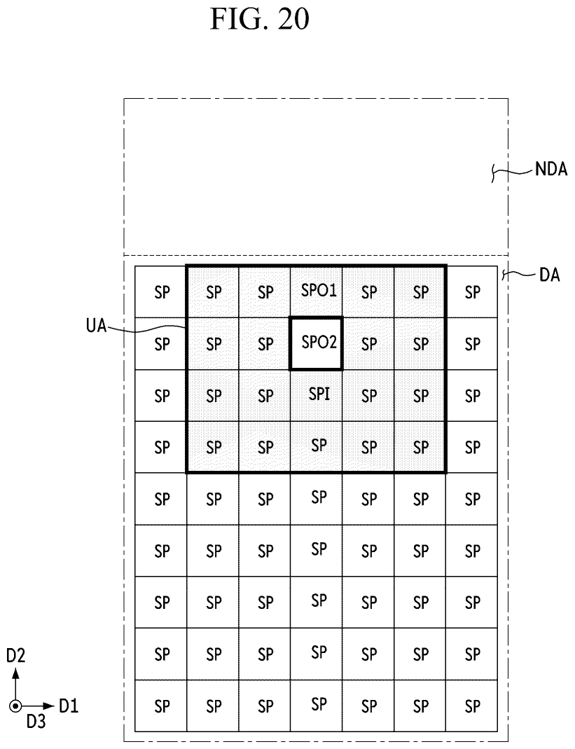

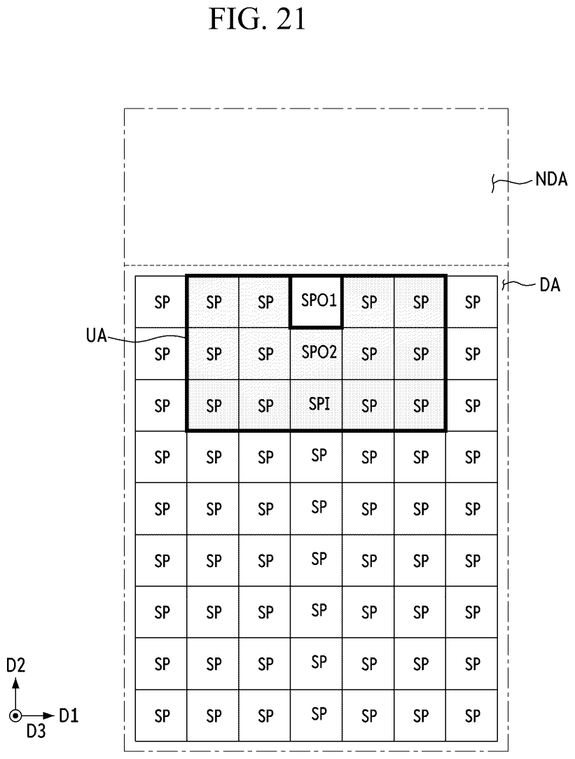

FIG. 16 is a cross-sectional view for explaining the movement of hydrogen atoms in a unit area including an inner subpixel. FIG. 17 is a cross-sectional view for explaining the movement of hydrogen atoms in a unit area including a second outer subpixel. FIG. 18 is a cross-sectional view for explaining the movement of hydrogen atoms in a unit area including a first outer subpixel. FIG. 19 is a plan view for explaining the movement of hydrogen atoms in the unit area including the inner subpixel. FIG. 20 is a plan view for explaining the movement of hydrogen atoms in the unit area including the second outer subpixel. FIG. 21 is a plan view for explaining the movement of hydrogen atoms in the unit area including the first outer subpixel.

As described above, the number of subpixels SP per unit area UA may decrease in the order of the inner subpixel SPI, the second outer subpixel SPO2, and the first outer subpixel SPO1. A subpixel SP at the center of a unit area UA may include an oxide transistor Tox. As the number of subpixels SP per unit area UA decreases, the amount of titanium (Ti), the number of contact holes CH, etc. that affect the element characteristics of the oxide transistor Tox decrease.

Referring to FIGS. 16 and 19, 17 and 20, 18 and 21, for example, the number of subpixels SP, the amount of titanium (Ti), and the number of contact holes CH that affect the behavior of the oxide transistor Tox included in the inner subpixel SPI may be smallest in the first outer subpixel SPO1 and largest in the inner subpixel SPI.

Because numerous subpixels SP are located in the display area DA, most of the subpixels SP may have element characteristics similar to those of the inner subpixel SPI. Therefore, the element characteristics of the first outer subpixel SPO1 or the second outer subpixel SPO2 may be relatively different from those of the inner subpixel SPI.

As described above, the element characteristics of the oxide transistor Tox may be affected by the amount of titanium (Ti) in the first connection metal layer SD1 and the third gate metal layer GAT3 located adjacent to the oxide transistor Tox, the number of contact holes CH, the distance from each of the first connection metal layer SD1, the third gate metal layer GAT3, and the control holes CH, etc. Numerous subpixels SP are arranged in the display area DA, and the display device is designed to substantially uniformly match the element characteristics of most of the subpixels SP. Because the number of inner subpixels SPI is relatively greater than the number of first outer subpixels SPO1 or second outer subpixels SPO2, the thickness of each of the insulating layers, the material of each of the insulating layers, etc. may be designed based on the inner subpixel SPI. In this case, the element characteristics of the oxide transistor Tox included in the first outer subpixel SPO1 or the like and the element characteristics of the oxide transistor Tox included in the inner subpixel SPI may be different.

In the display device according to embodiments of the present specification, a plurality of dummy contact holes DCH, dummy lines DML, etc. may be additionally placed so that the element characteristics of a subpixel SP located relatively close to the non-display area NDA can be made similar to those of the inner subpixel SPI. Accordingly, the element characteristics of all subpixels SP located in the display area DA may become substantially uniform, and thus the display quality of the display device can be improved.

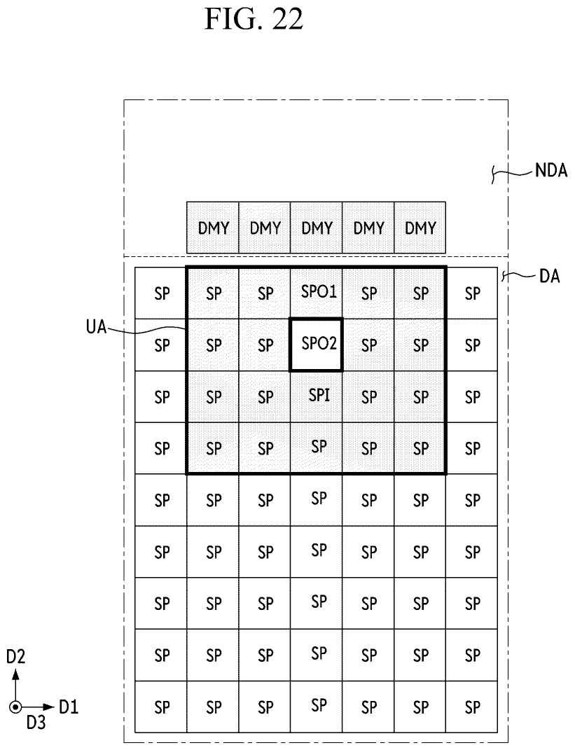

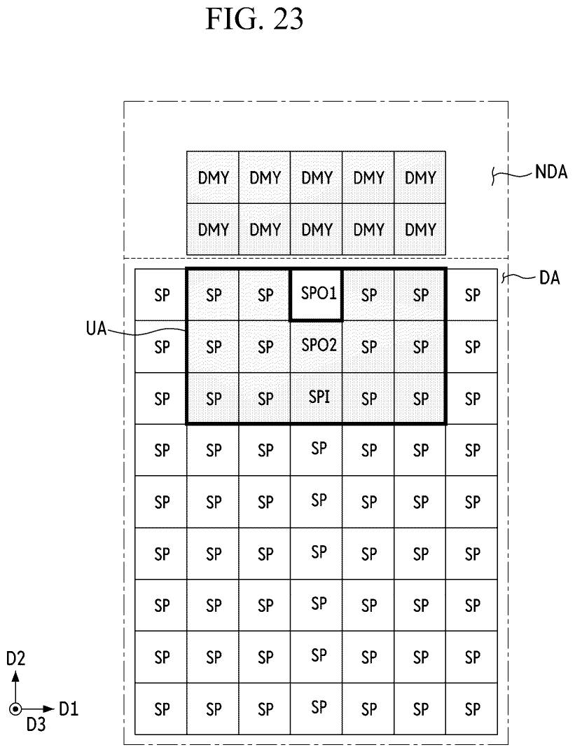

FIGS. 22 and 23 are plan views of display devices according to embodiments of the present specification.

Referring to FIGS. 22 and 23, a plurality of dummy elements may be arranged in a non-display area NDA so that the amount of titanium (Ti) in a first connection metal layer SD1 and a third gate metal layer GAT3, the number of contact holes CH, etc. that affect a second outer subpixel SPO2 per unit area UA can be matched with those of an inner subpixel SPI. In one or more embodiments, each of the dummy elements may include a dummy contact hole DCH, a dummy line DML, and a dummy active layer DACT. The dummy line DML may be a first gate metal layer GAT1, a second gate metal layer GAT2, a third gate metal layer GAT3, a first connection metal layer SD1, or a second connection metal layer SD2 depending on the structure of the dummy contact hole DCH.

If FIGS. 22 and 23 are compared, a first outer subpixel SPO1 may be closer to the non-display area NDA than the second outer subpixel SPO2. The dummy elements may be doubly formed so that the element characteristics of the first outer subpixel SPO1 as well as the second outer subpixel SPO2 can be substantially uniformly matched with the element characteristics of the inner subpixel SPI. An outermost boundary line of an area where the dummy elements are located may be set based on the element characteristics of the first outer subpixel SPO1.

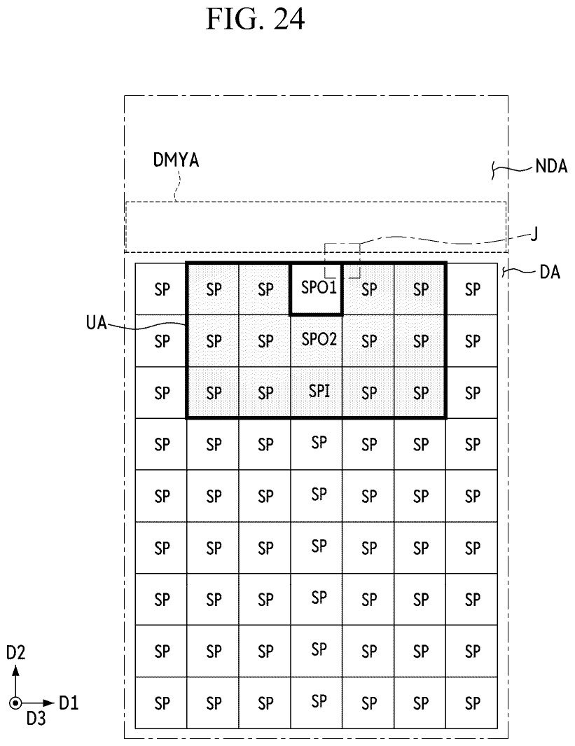

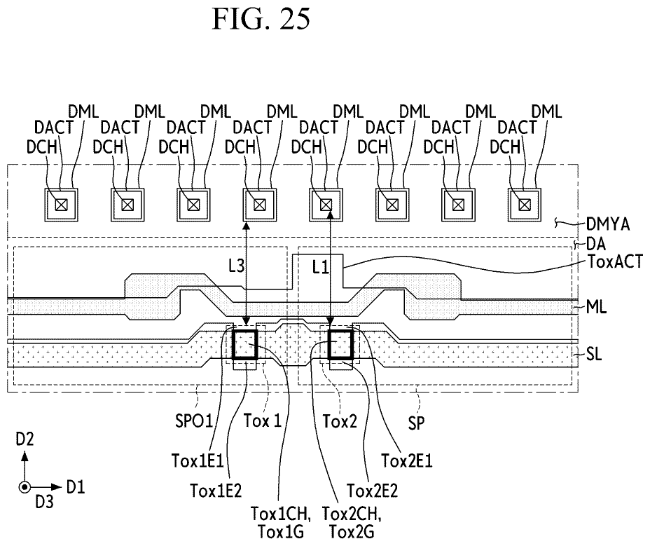

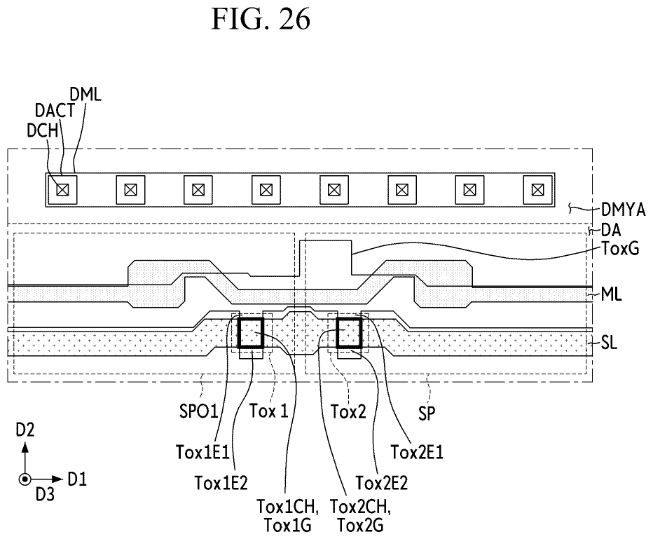

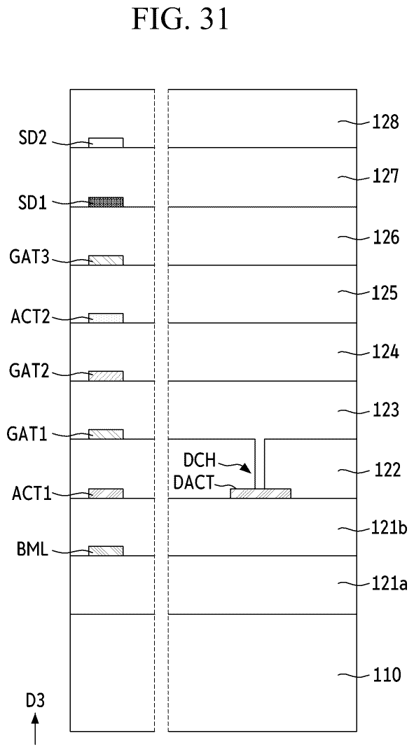

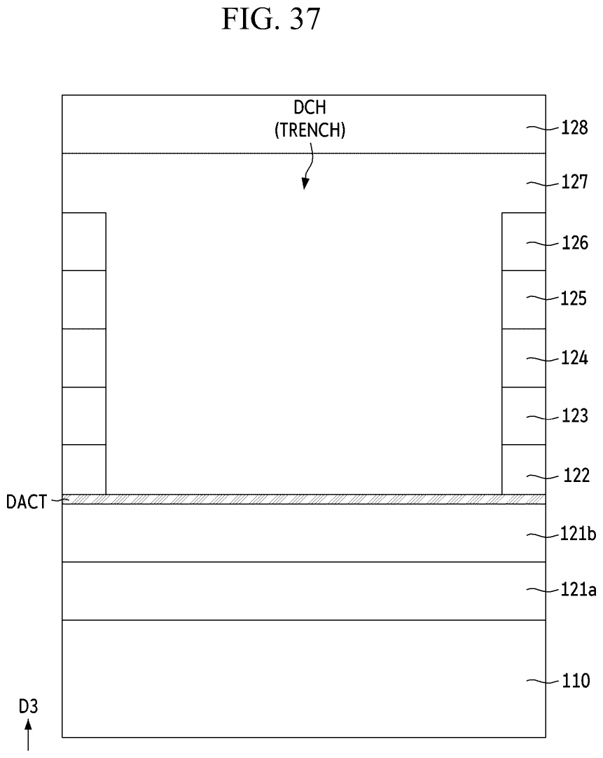

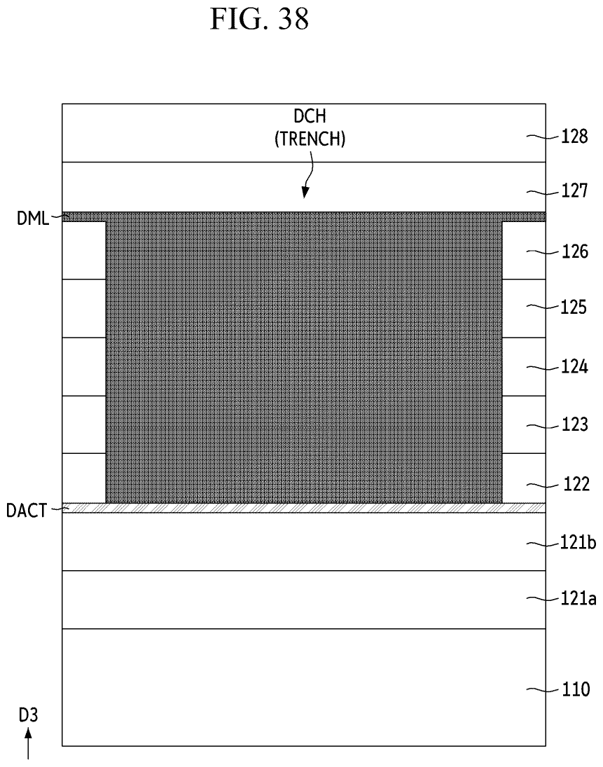

FIG. 24 is a plan view of a display device according to one or more embodiments of the present specification. FIG. 25 is a partial enlarged view of area J of FIG. 24. FIGS. 26 through 30 are partial enlarged views of various modifications of FIG. 25. FIGS. 31 through 38 are cross-sectional views illustrating dummy contact holes according to embodiments of the present specification.

Referring to FIGS. 24 and 25, a first outer subpixel SPO1 may include a scan line SL and a metal line ML extending in a first direction D1, an electrode, and a channel portion of an oxide transistor Tox, etc. The first outer subpixel SPO1 may include a first oxide transistor Tox1.

A subpixel SP may include the scan line SL and the metal line ML extending in the first direction D1, an electrode, and a channel portion of an oxide transistor Tox, etc. The subpixel SP may include a second oxide transistor Tox2. The second oxide transistor Tox2 and the first oxide transistor Tox1 may perform the same function in the circuit diagram in the subpixel SP and the first outer subpixel SPO1, respectively. For example, each of the second oxide transistor Tox2 and the first oxide transistor Tox1 may be a third transistor or a fourth transistor in the circuit diagram described above, but embodiments of the present specification are not limited to this example.

The first oxide transistor Tox1 and/or the second oxide transistor Tox2 according to one or more embodiments may be located relatively closer to a non-display area NDA than a first transistor, which is a driving transistor. Each of the first oxide transistor Tox1 and the second oxide transistor Tox2 may be a switching transistor in a subpixel SP. The first oxide transistor Tox1 and the second oxide transistor Tox2 may be located at an outermost position of a display area DA. A gate electrode Tox1G of the first oxide transistor Tox1 and a gate electrode Tox2G of the second oxide transistor Tox2 may be located in the same layer, and may be physically connected to each other. For example, the gate electrode Tox1G of the first oxide transistor Tox1 and the gate electrode Tox2G of the second oxide transistor Tox2 may both be included in the scan line SL, and the scan line SL may supply a gate signal to the first oxide transistor Tox1 and the second oxide transistor Tox2.

The scan line SL may include an oxide active layer ToxACT including an electrode and a channel portion of an oxide transistor Tox. The oxide active layer ToxACT may include a protruding portion extending toward the first outer subpixel SPO1 and a protruding portion extending toward the subpixel SP. The protruding portion extending toward the first outer subpixel SPO1 may include a first electrode Tox1E1 of the first oxide transistor Tox1, a second electrode Tox1E2 of the first oxide transistor Tox1, and a channel portion Tox1CH of the first oxide transistor Tox1 located between the first electrode Tox1E1 of the first oxide transistor Tox1 and the second electrode Tox1E2 of the first oxide transistor Tox1.

The protruding portion extending toward the subpixel SP may include a first electrode Tox2E1 of the second oxide transistor Tox2, a second electrode Tox2E2 of the second oxide transistor Tox2, and a channel portion Tox2CH of the second oxide transistor Tox2 located between the first electrode Tox2E1 of the second oxide transistor Tox2 and the second electrode Tox2E2 of the second oxide transistor Tox2.

The channel portion Tox1CH of the first oxide transistor Tox1 may overlap the scan line SL in a third direction D3, and a portion of the scan line SL, which overlaps the channel portion Tox1CH of the first oxide transistor Tox1, may become the gate electrode Tox1G of the first oxide transistor Tox1. The channel portion Tox2CH of the second oxide transistor Tox2 may overlap the scan line SL in the third direction D3, and a portion of the scan line SL, which overlaps the channel portion Tox2CH of the second oxide transistor Tox2, may become the gate electrode Tox2G of the second oxide transistor Tox2.

As described above, the first oxide transistor Tox1 and the second oxide transistor Tox2 located at the outermost position of the display area DA may be included in the first outer subpixel SPO1 and the subpixel SP, respectively. The subpixel SP may also correspond to the first outer subpixel SPO1 located at the outermost position of the display area DA in a second direction D2.

One or more embodiments may include a plurality of dummy elements included in a dummy area DMYA to reduce a difference between the element characteristics of the first oxide transistor Tox1 located at the outermost position of the display area DA and the element characteristics of an oxide transistor Tox located in an inner subpixel SPI.

In a process of manufacturing the display device, a plurality of insulating layers, etc., which supply hydrogen (H) to an oxide semiconductor layer, are formed to a substantially uniform thickness throughout the display area DA. Therefore, the insulating layers are not taken into consideration in the determination of the amount of hydrogen (H) in the oxide semiconductor layer.

In one or more embodiments, the amount of titanium (Ti), the number of contact holes CH, etc., which are variables that can affect the determination of the amount of hydrogen (H) in the oxide semiconductor layer toward the outside of the display area DA, may be made the same in the inner subpixel SPI and the first outer subpixel SPO1.

Therefore, each of the dummy elements may include a dummy contact hole DCH and a dummy line DML, and the dummy line DML may include titanium (Ti). However, embodiments of the present specification are not limited to this case. Each of the dummy elements may further include a dummy active layer DACT. A first active layer ACT1 may include the dummy active layer DACT. The dummy active layer DACT is not directly related to the determination of the amount of hydrogen (H), but may be additionally formed in the dummy area DMYA for consistency with a process of forming the first active layer ACT1 during the process of manufacturing the display device. In addition, the dummy active layer DACT may correspond to the first active layer ACT1 formed in the display area DA. Because the dummy active layer DACT and the dummy contact hole DCH are formed, substantial environmental uniformity with the first active layer ACT1 located in the display area DA, and a contact hole connecting the first active layer ACT1 to a line, can be achieved.

The dummy line DML is a metal layer that can affect the determination of the amount of hydrogen (H) in the oxide semiconductor layer. For example, the dummy line DML may be any line including titanium (Ti). The dummy contact hole DCH brings the dummy line DML and the dummy active layer DACT into contact with each other. Because the dummy active layer DACT is included in the first active layer ACT1, the dummy contact hole DCH may be formed (for example): only in a first gate-insulating layer 122; only in the first gate-insulating layer 122 and a second gate-insulating layer 123; only in the first gate-insulating layer 122, the second gate-insulating layer 123, and a first interlayer insulating film 124; only in the first gate-insulating layer 122, the second gate-insulating layer 123, the first interlayer insulating film 124, and a third gate-insulating layer 125; or only in the second gate-insulating layer 123, the first interlayer insulating film 124, the third gate-insulating layer 125, and a second interlayer insulating film 126.

Referring to FIG. 31, when the dummy contact hole DCH is formed only in the first gate-insulating layer 122, the dummy line DML may be included in a first gate metal layer GAT1 located on the first gate-insulating layer 122. The dummy line DML included in the first gate metal layer GAT1 may be electrically connected or in contact with the dummy active layer DACT through the dummy contact hole DCH formed in the first gate-insulating layer 122.

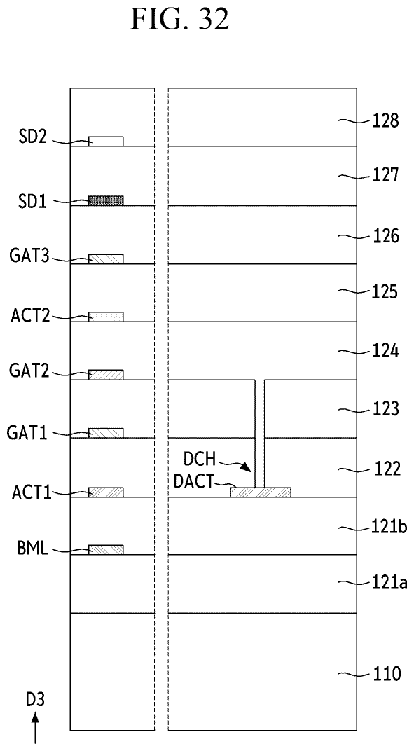

Referring to FIG. 32, when the dummy contact hole DCH is formed only in the first gate-insulating layer 122 and the second gate-insulating layer 123, the dummy line DML may be included in a second gate metal layer GAT2 located on the second gate-insulating layer 123. The dummy line DML included in the second gate metal layer GAT2 may be electrically connected or in contact with the dummy active layer DACT through the dummy contact hole DCH formed in the first gate-insulating layer 122 and the second gate-insulating layer 123.

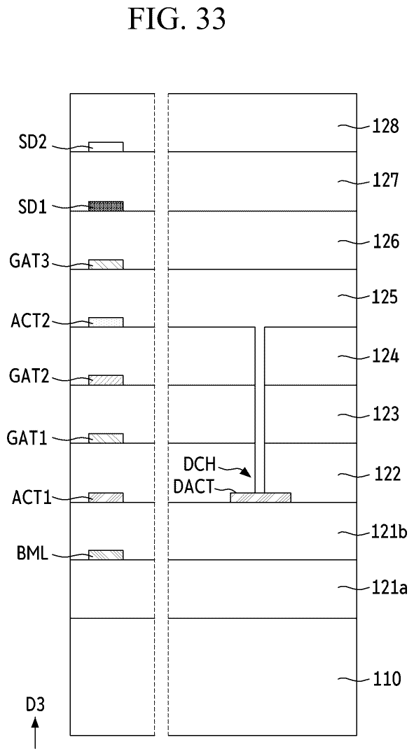

Referring to FIG. 33, when the dummy contact hole DCH is formed only in the first gate-insulating layer 122, the second gate-insulating layer 123, and the first interlayer insulating film 124, the dummy line DML may be included in a second active layer ACT2 located on the first interlayer insulating film 124. The dummy line DML included in the second active layer ACT2 may be electrically connected or in contact with the dummy active layer DACT through the dummy contact hole DCH formed in the first gate-insulating layer 122, the second gate-insulating layer 123, and the first interlayer insulating film 124.

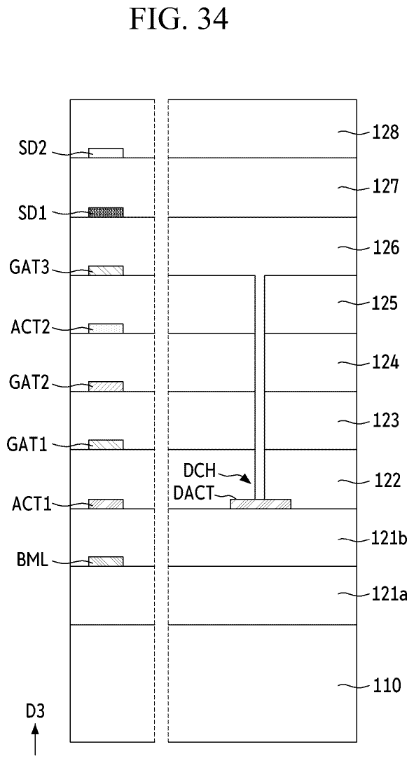

Referring to FIG. 34, when the dummy contact hole DCH is formed only in the first gate-insulating layer 122, the second gate-insulating layer 123, the first interlayer insulating film 124, and the third gate-insulating layer 125, the dummy line DML may be included in a third gate metal layer GAT3 located on the third gate-insulating layer 125. The dummy line DML included in the third gate metal layer GAT3 may be electrically connected or in contact with the dummy active layer DACT through the dummy contact hole DCH formed in the first gate-insulating layer 122, the second gate-insulating layer 123, the first interlayer insulating film 124, and the third gate-insulating layer 125.

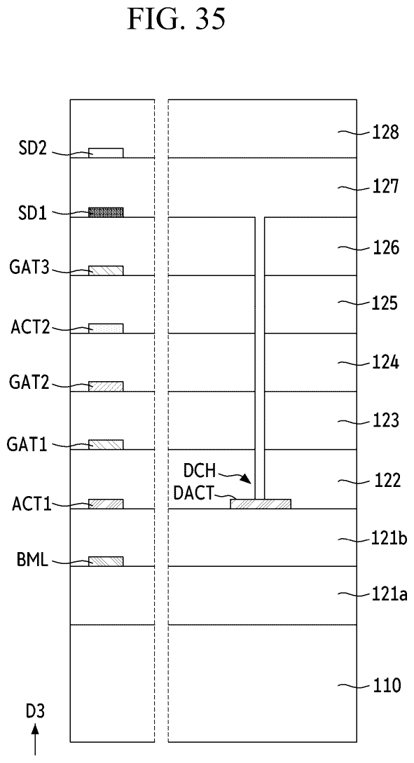

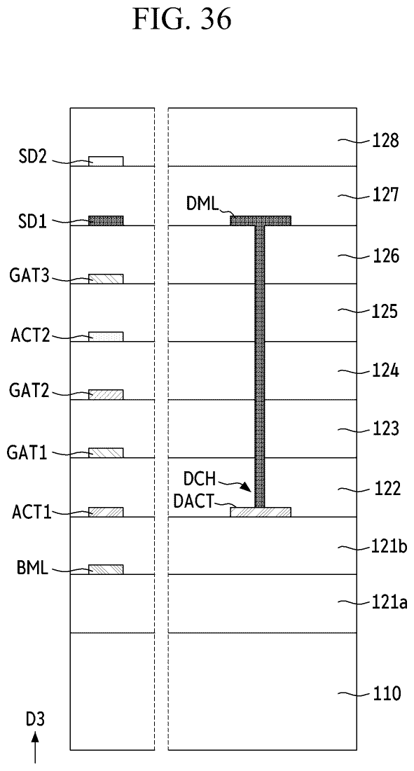

Referring to FIGS. 35 and 36, when the dummy contact hole DCH is formed only in the first gate-insulating layer 122, the second gate-insulating layer 123, the first interlayer insulating film 124, the third gate-insulating layer 125, and the second interlayer insulating film 126, the dummy line DML may be included in a first connection metal layer SD1 located on the second interlayer insulating film 126. The dummy line DML included in the first connection metal layer SD1 may be electrically connected or in contact with the dummy active layer DACT through the dummy contact hole DCH formed in the first gate-insulating layer 122, the second gate-insulating layer 123, the first interlayer insulating film 124, the third gate-insulating layer 125, and the second interlayer insulating film 126.

The dummy line DML may be placed in any layer, generally, and may be a line including titanium (Ti). In addition, the dummy contact hole DCH may be formed in corresponding insulating layers according to the formation position of the dummy line DML so that the dummy active layer DACT and the dummy line DML can contact each other. In one or more embodiments, the dummy line DML may also be included in a second connection metal layer SD2. In this case, the dummy contact hole DCH may be formed in the first gate-insulating layer 122, the second gate-insulating layer 123, the first interlayer insulating film 124, the third gate-insulating layer 125, the second interlayer insulating film 126, and a first planarization layer 127.

A distance L1 between an oxide transistor Tox (Tox1, Tox2) and the dummy contact hole DCH, a distance L3 between the oxide transistor Tox (Tox1, Tox2) and the dummy line DML, etc. may be freely designed according to the amount of hydrogen (H) to be controlled.

Referring to FIG. 26, the dummy line DML may be integrally formed to overlap all of a plurality of dummy contact holes DCH. In one or more embodiments, the size of the dummy line DML, the number of dummy contact holes DCH overlapping the dummy line DML, etc. may be freely controlled. The dummy line DML may also overlap a plurality of dummy contact holes DCH.

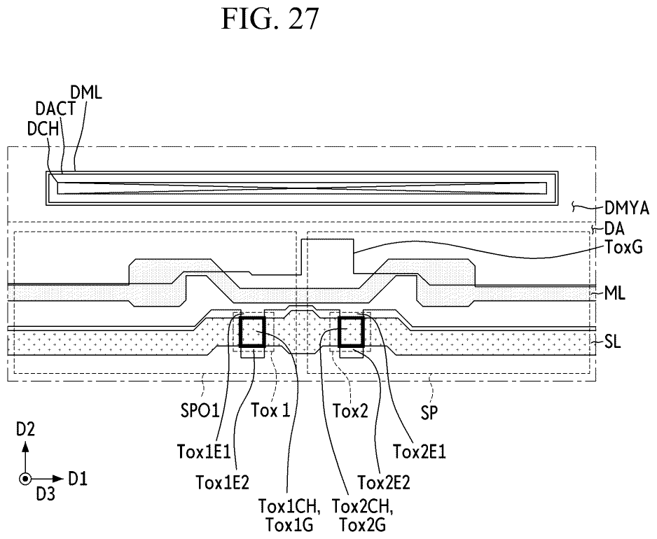

Referring to FIGS. 27, 37, and 38, the size of the dummy contact hole DCH can also be freely controlled. For example, the dummy contact hole DCH may extend in the first direction D1. In this case, the shape of the dummy contact hole DCH may correspond to that of a trench TRENCH.

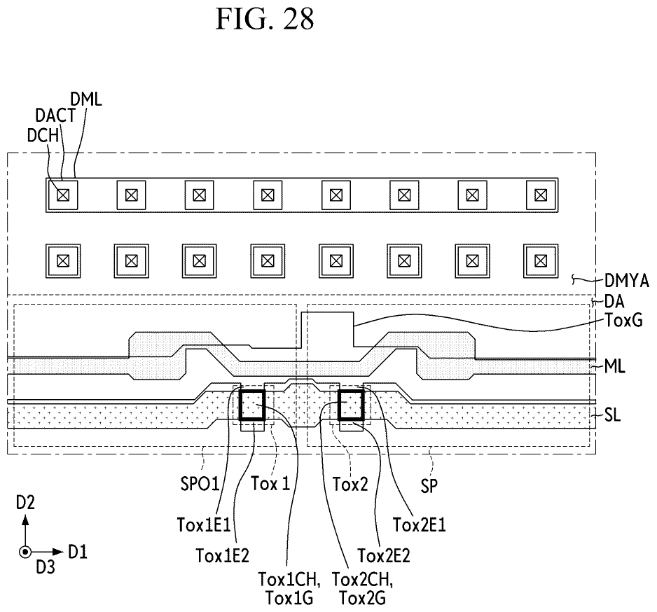

Referring to FIGS. 28 through 30, display devices according to various embodiments may include dummy elements doubly located in the dummy area DMYA. As described above, an outermost boundary line of an area where the dummy elements are located may be set based on the element characteristics of the first outer subpixel SPO1.

The dummy elements may be divided into a first row and a second row. The specific shape of the dummy elements formed in the first row may be different from the specific shape of the dummy elements formed in the second row.

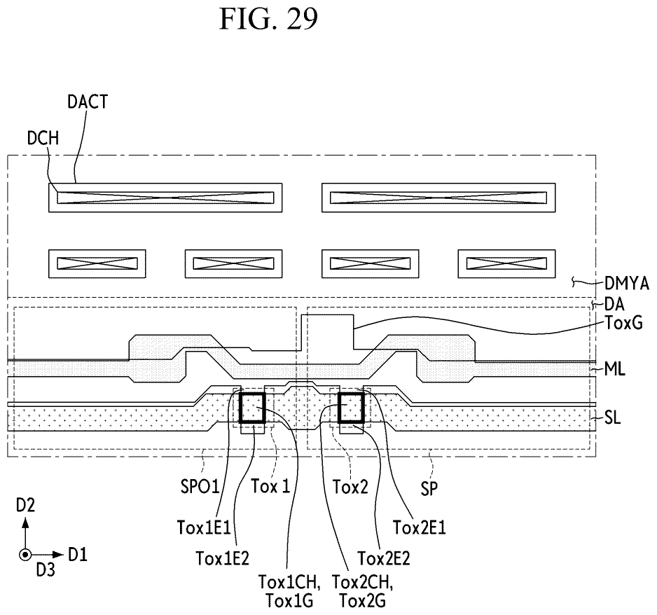

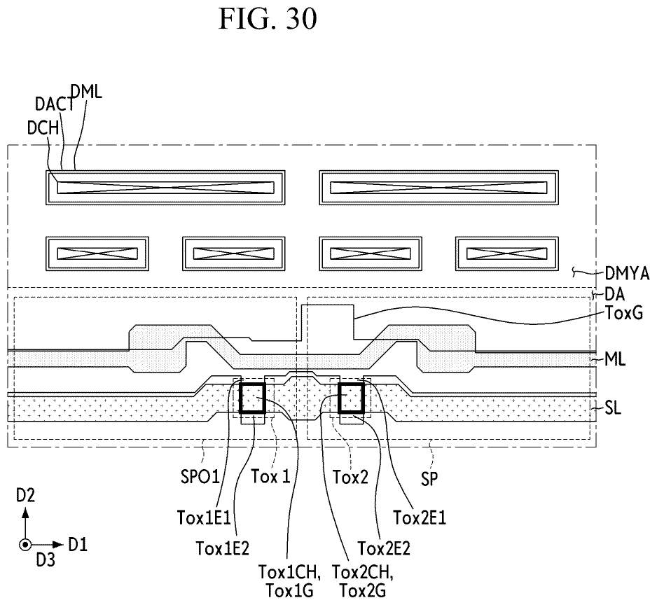

For example, as illustrated in FIG. 28, in the first row, a single dummy line DML may overlap a plurality of dummy contact holes DCH. However, in the second row, a plurality of dummy lines DML may each overlap one dummy contact hole DCH. Alternatively, as illustrated in FIGS. 29 and 30, dummy lines DML may have different lengths in the first direction D1.

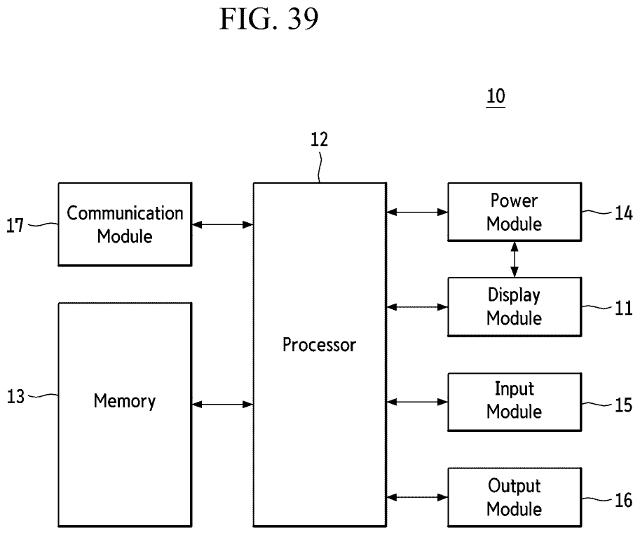

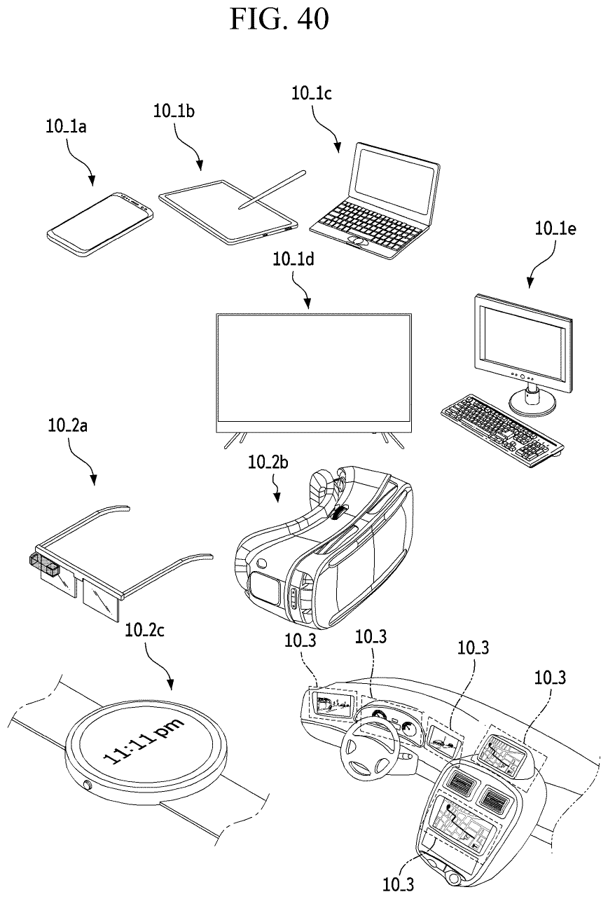

FIG. 39 is a block diagram of an electronic device according to one or more embodiments of the present specification. FIG. 40 is a schematic diagram of electronic devices according to various embodiments of the present specification.

Referring to FIG. 39, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information suitable for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device. The power module 14 may include a power conversion module. The power conversion module may generate power suitable for the operation of the electronic device 10 by converting power supplied by the power supply module.

At least one of the elements of the electronic device 10 described above may be included in a display device according to the above-described embodiments. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 10.

Referring to FIG. 40, various electronic devices to which a display device according to embodiments of the present specification is applied may include image display electronic devices, such as a smartphone 10_1a, a tablet PC 10_1b, a laptop 10_1c, a television 10_1d, and a desk monitor 10_1e. In addition, the various electronic devices to which the display device according to the embodiments of the present specification is applied may include wearable electronic devices including a display module, such as smart glasses 10_2a, a head-mounted display 10_2b and a smart watch 10_2c, and vehicle electronic devices 10_3 including a display module, such as a center information display (CID) and a room mirror display placed on an instrument cluster, center fascia and dashboard of a vehicle.

Although embodiments of the disclosure have been described above with reference to the accompanying drawings, it will be understood by those having ordinary skill in the technical field to which the disclosure belongs that the disclosure may be practiced in other specific forms without altering the idea or aspects of the disclosure. It should therefore be understood that the embodiments described above are merely examples in all respects and are not intended to be limiting.

What is claimed is:

1. A display device comprising:
a display area comprising subpixels comprising a driving transistor and a switching transistor; and
a non-display area closer to the switching transistor than to the driving transistor, surrounding the display area, defining a dummy contact hole penetrating a first gate-insulating layer covering a first active layer, and comprising a dummy line overlapping the dummy contact hole.

2. The display device of claim 1, wherein a second active layer above the first gate-insulating layer comprises:
a first electrode of the switching transistor;
a second electrode of the switching transistor; and
a channel portion of the switching transistor between the first electrode of the switching transistor and the second electrode of the switching transistor.

3. The display device of claim 2, wherein the first active layer comprises a silicon semiconductor, and
wherein the second active layer comprises an oxide semiconductor.

4. The display device of claim 1, wherein the first active layer comprises a dummy active layer overlapping the dummy contact hole.

5. The display device of claim 1, wherein the dummy contact hole penetrates a second gate-insulating layer covering a first gate metal layer above the first gate-insulating layer.

6. The display device of claim 5, wherein the dummy contact hole penetrates a first interlayer insulating film covering a second gate metal layer above the second gate-insulating layer.

7. The display device of claim 6, wherein a second active layer above the first interlayer insulating film comprises:
a first electrode of the switching transistor;
a second electrode of the switching transistor; and
a channel portion of the switching transistor between the first electrode of the switching transistor and the second electrode of the switching transistor.

8. The display device of claim 7, wherein the dummy contact hole penetrates a third gate-insulating layer covering the second active layer.

9. The display device of claim 8, wherein a third gate metal layer above the third gate-insulating layer comprises a gate electrode of the switching transistor.

10. The display device of claim 9, wherein the dummy contact hole penetrates a second interlayer insulating film covering the third gate metal layer.

11. The display device of claim 10, wherein a first connection metal layer above the second interlayer insulating film comprises the dummy line.

12. The display device of claim 1, wherein the dummy line comprises titanium (Ti).

13. The display device of claim 1, wherein the first active layer comprises a dummy active layer overlapping the dummy contact hole, and
wherein the dummy line contacts the dummy active layer through the dummy contact hole.

14. The display device of claim 1, wherein the dummy line is at a layer above a gate electrode of the switching transistor.

15. The display device of claim 1, wherein the subpixels comprise a light-emitting element comprising an anode above a first connection metal layer comprising the dummy line, a cathode, and a light-emitting layer between the anode and the cathode.

16. An electronic device comprising:
a processor for providing an image signal;
a power module for supplying power; and
a display module for receiving the image signal from the processor, for receiving the power from the power module, for displaying an image, and comprising:
a display area comprising subpixels comprising a driving transistor and a switching transistor; and
a non-display area closer to the switching transistor than to the driving transistor, surrounding the display area, defining a dummy contact hole penetrating a first gate-insulating layer covering a first active layer, and comprising a dummy line overlapping the dummy contact hole.

17. The electronic device of claim 16, wherein a second active layer above the first gate-insulating layer comprises:
a first electrode of the switching transistor;
a second electrode of the switching transistor; and
a channel portion of the switching transistor between the first electrode of the switching transistor and the second electrode of the switching transistor.

18. The electronic device of claim 16, wherein the first active layer comprises a dummy active layer overlapping the dummy contact hole.

19. The electronic device of claim 18, wherein the dummy line contacts the dummy active layer through the dummy contact hole.

20. The electronic device of claim 16, wherein the dummy line is at a layer above a gate electrode of the switching transistor.
